(19) United States
(12) Patent Application Publication
(10) Pub. No.: US 2026/0321314 A1
(43) Pub. Date: Oct. 15, 2026

(54) APPARATUS AND METHODS FOR PROXY-BASED TIMING CONTROL FOR MEMORY OPERATIONS

(71) Applicant: Sandisk Technologies, Inc., Milpitas, CA (US)

(72) Inventors: V.S.N.K. Chaitanya G, Bengaluru (IN); Pradeep ANANTULA, Bengaluru (IN)

(73) Assignee: Sandisk Technologies, Inc., Milpitas, CA (US)

(21) Appl. No.: 19/179,195

(22) Filed: Apr. 15, 2025

(51) Int. Cl. G11C 16/26; G11C 16/04; G11C 16/08; G11C 16/10

(52) U.S. Cl. CPC G11C 16/26; G11C 16/0483; G11C 16/08; G11C 16/10

(57) ABSTRACT

An apparatus is provided that includes a block of non-volatile memory cells, word lines coupled to the non-volatile memory cells, and a charge pump including an output terminal coupled to the word lines. The charge pump is configured to provide an output signal at the output terminal. The output signal has a rate that is based on a first count of a number of programmed word lines in the plurality of word lines.

### BACKGROUND

Semiconductor memory is widely used in various electronic devices such as cellular telephones, digital cameras, personal digital assistants, medical electronics, mobile computing devices, servers, solid state drives, non-mobile computing devices and other devices. Semiconductor memory may be non-volatile memory or volatile memory. A non-volatile memory allows information to be stored and retained even when the non-volatile memory is not connected to a source of power (e.g., a battery).

Non-volatile memory devices include one or more memory chips having multiple arrays of memory cells. The memory arrays may have associated decoders and circuits for performing read, write, and erase operations. Memory cells within the arrays may be arranged in horizontal rows and vertical columns. Each row may be addressed by a word line, and each column may be addressed by a bit line. Data may be loaded into columns of the array using a series of data busses. Each column may hold a predefined unit of data, for instance, a word encompassing two bytes of information.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 2C is a block diagram depicting an embodiment of a sense block of FIGS. 2A-2B.

FIGS. 3A and 3B depict different embodiments of integrated memory assemblies.

FIG. 4A is a perspective view of a portion of one embodiment of a monolithic three dimensional memory array.

FIG. 4B is a block diagram of one embodiment of a memory array having four planes.

FIG. 4C depicts a top view of a portion of one embodiment of a block of memory cells.

FIG. 4D depicts a cross sectional view of a portion of one embodiment of a block of memory cells.

FIG. 4E depicts a cross sectional view of a portion of one embodiment of a block of memory cells.

FIG. 4F is a cross sectional view of one embodiment of a vertical column of memory cells.

FIG. 4G is a schematic of a plurality of NAND strings in multiple regions of a same block.

FIG. 5 is a block diagram of one embodiment of a memory array having four planes.

FIG. 6A depicts example threshold voltage distributions.

FIG. 6B depicts an example data coding scheme for the data states of FIG. 6A.

FIG. 7A is a diagram depicting peak and average device current versus block openness.

FIG. 7B is a simplified diagram depicting a charge pump having an output coupled to a block of memory cells of memory array.

FIG. 7C is a simplified diagram of an embodiment of a memory system that includes a memory array having multiple planes, each plane including multiple blocks of memory cells.

FIG. 8A depicts a graph of charge pump output voltage versus time.

FIG. 8B depicts graphs of charge pump output voltage versus time for three different first counter values for a program operation.

FIG. 9 is a flow diagram of a process for determining second counter values for programming operations for a block of memory cells.

FIG. 10A is a simplified block diagram of an embodiment of an n-bit binary adder.

FIG. 10B is a diagram of an embodiment of a full-adder circuit.

FIG. 11 lists example second ramp rate scale factor values for a program operation.

FIG. 12 lists example charge pump ramp time reductions for program and read operations.

FIG. 13 is a flow diagram of a process for reading non-volatile memory cells coupled to a word line in a block of non-volatile memory cells.

### DETAILED DESCRIPTION

Technology is described for timing control for memory operations such as program and read operations. In an embodiment, for each block of memory cells in a memory array a corresponding first counter C1 is maintained. In embodiments, the corresponding first counter C1 equals a number of programmed word lines in the block of memory cells. In embodiments, the corresponding first counter C1 is used as a proxy for the relative capacitive load of the block as seen by the charge pump coupled to the block, and a ramp rate of the charge pump is adjusted based on corresponding first counter C1.

In an embodiment, for each block of memory cells in a memory array a corresponding second counter C2 also is maintained. In embodiments, the corresponding second counter C2 equals an average programmed state of programmed word lines in the block of memory cells. In embodiments, the corresponding second counter C2 is used as a proxy for the relative capacitive load of the block as seen by the charge pump coupled to the block, and a ramp rate of the charge pump is adjusted based on corresponding second counter C2.

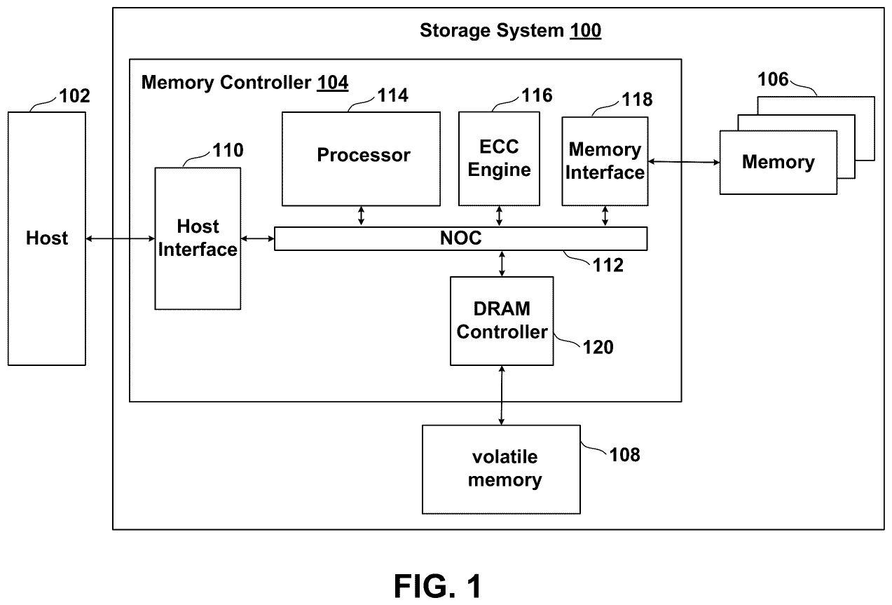

FIG. 1 is a block diagram of one embodiment of a storage system 100 that implements the proposed technology described herein. In an embodiment, storage system 100 is a solid state drive (“SSD”). Storage system 100 also can be a memory card, USB drive or other type of storage system. The proposed technology is not limited to any one type of memory system.

Storage system 100 is connected to a host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 104 connected to non-volatile memory 106 and local high speed volatile memory 108 (e.g., DRAM). Local high speed volatile memory 108 is used by memory controller 104 to perform certain functions. For example, local high speed volatile memory 108 stores logical to physical address translation tables (“L2P tables”).

Memory controller 104 includes a host interface 110 that is connected to and in communication with host 102. In an embodiment, host interface 110 implements a NVM Express (NVMe) over PCI Express (PCIe). Other interfaces can also be used, such as SCSI, SATA, etc. Host interface 110 also is connected to a network-on-chip (NOC) 112.

A NOC is a communication subsystem on an integrated circuit. NOC's can span synchronous and asynchronous clock domains or use un-clocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs.

The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 112 can be replaced by a bus.

Connected to and in communication with NOC 112 is a processor 114, an ECC engine 116, a memory interface 118, and a DRAM controller 120. DRAM controller 120 is used to operate and communicate with local high speed volatile memory 108 (e.g., DRAM). In other embodiments, local high speed volatile memory 108 can be SRAM or another type of volatile memory.

Processor 114 performs the various controller memory operations, such as programming, erasing, reading, and memory management processes. In an embodiment, processor 114 is programmed by firmware. In other embodiments, processor 114 is a custom and dedicated hardware circuit without any software. Processor 114 also implements a translation module, as a software/firmware process or as a dedicated hardware circuit.

In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 104 (e.g., the translation module) performs address translation between the logical addresses used by the host and the physical addresses used by the memory die.

One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables.

Instead, the logical address to physical address tables (or L2P tables) can be any type of data structure. In some examples, the memory space of a storage system is so large that the local memory 108 cannot hold all of the L2P tables. In such a case, the entire set of L2P tables are stored in non-volatile memory 106 and a subset of the L2P tables are cached (L2P cache) in the local high speed volatile memory 108.

ECC engine 116 performs error correction services. For example, ECC engine 116 performs data encoding and decoding, as per the implemented ECC technique. In an embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Memory interface 118 communicates with non-volatile memory 106. In an embodiment, memory interface provides a Toggle Mode interface. Other interfaces also can be used. In some example implementations, memory interface 118 (or another portion of controller 104) implements a scheduler and buffer for transmitting data to and receiving data from one or more memory die.

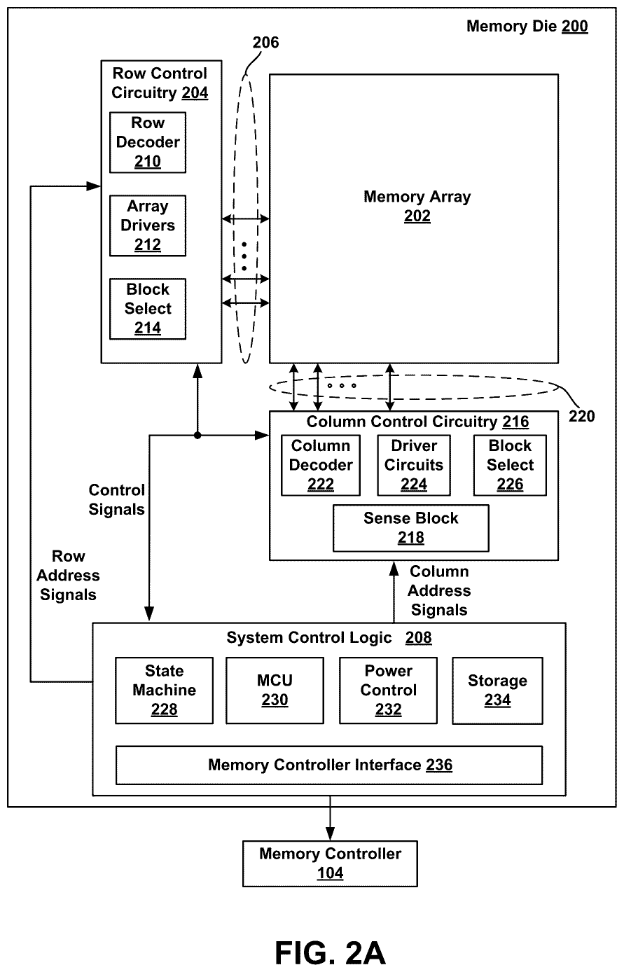

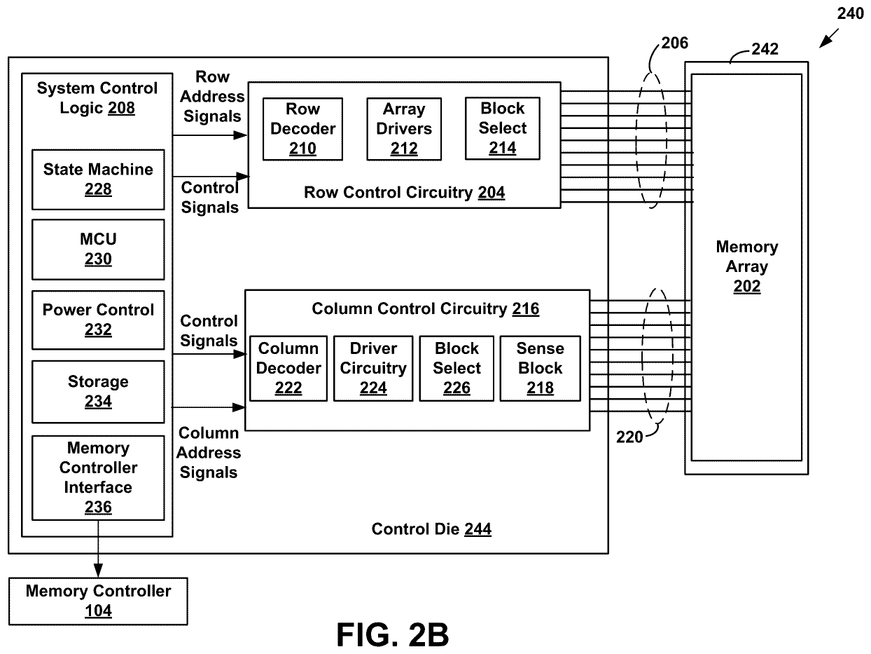

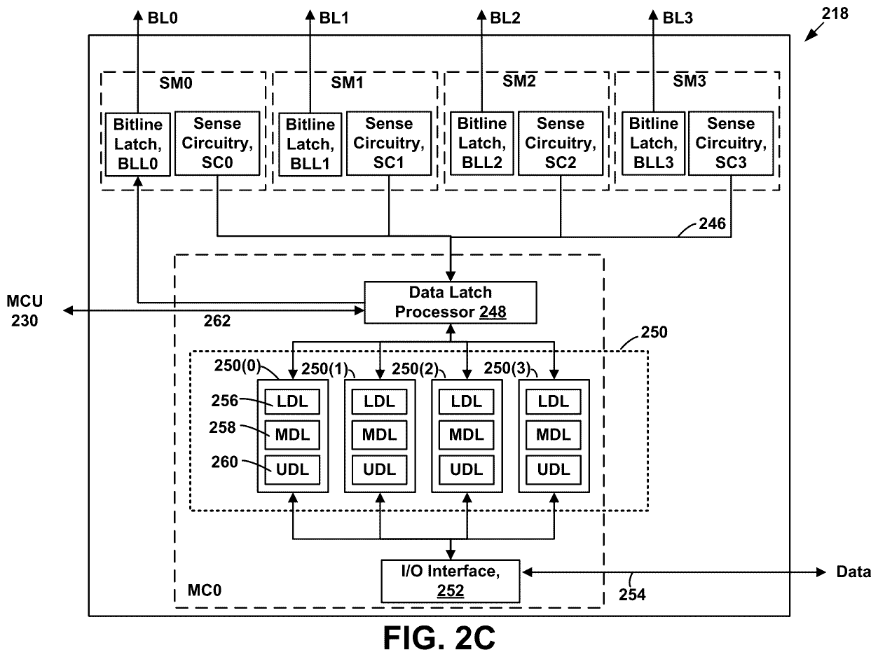

In an embodiment, non-volatile memory 106 includes one or more memory die. FIG. 2A is a functional block diagram of an embodiment of a memory die 200 that includes non-volatile memory 106. Each of the one or more memory die of non-volatile memory 106 can be implemented as memory die 200 of FIG. 2A. The components depicted in FIG. 2A are electrical circuits.

Memory die 200 includes a memory array 202 that can include non-volatile memory cells, as described in more detail below. The array terminal lines of memory array 202 include various layer(s) of word lines organized as rows, and various layer(s) of bit lines organized as columns. However, other orientations also can be implemented.

Memory die 200 includes row control circuitry 204, whose outputs 206 are connected to respective word lines of the memory array 202. Row control circuitry 204 receives a group of M row address signals and one or more various control signals from system control logic circuit 208, and typically may include such circuits as row decoders 210, array terminal drivers 212, and block select circuitry 214 for both reading and writing (programming) operations.

Row control circuitry 204 also may include read/write circuitry. Memory die 200 also includes column control circuitry 216 including sense block 218 whose input/outputs 220 are connected to respective bit lines of memory array 202. Although only a single block is shown for memory array 202, a memory die can include multiple arrays that can be individually accessed.

Column control circuitry 216 receives a group of N column address signals and one or more various control signals from system control logic 208, and typically may include such circuits as column decoders 222, array terminal receivers or driver circuits 224, block select circuitry 226, as well as read/write circuitry, and I/O multiplexers.

System control logic 208 receives data and commands from memory controller 104 (FIG. 1) and provides output data and status to host 102. In some embodiments, system control logic 208 (which includes one or more electrical circuits) includes a state machine 228 that provides die-level control of memory operations.

In an embodiment, state machine 228 is programmable by software. In other embodiments, state machine 228 does not use software and is completely implemented in hardware (e.g., electrical circuits). In another embodiment, state machine 228 is replaced by a micro-controller or microprocessor, either on or off the memory chip.

System control logic 208 also can include a microcontroller (MCU) 230. In an embodiment, MCU 230 provides die-level control of memory operations. In an embodiment, MCU 230 is programmable by software. In other embodiments, MCU 230 does not use software and is completely implemented in hardware (e.g., electrical circuits).

System control logic 208 also can include a power control module 232 that controls the power and voltages supplied to the rows and columns of memory array 202 during memory operations and may include charge pumps and regulator circuits for regulating voltages. System control logic 208 includes storage 234 (e.g., RAM, registers, latches, etc.), which may be used to store parameters for operating memory array 202.

Commands and data are transferred between memory controller 104 and memory die 200 via memory controller interface 236 (also referred to as a “communication interface”). Memory controller interface 236 is an electrical interface for communicating with memory controller 104. Examples of memory controller interface 236 include a Toggle Mode Interface and an Open NAND Flash Interface (ONFI). Other I/O interfaces can also be used.

In some embodiments, all elements of memory die 200, including the system control logic 208, can be formed as part of a single die. In other embodiments, some or all of the system control logic 208 can be formed on a different die.

In an embodiment, memory array 202 comprises a three-dimensional memory array of non-volatile memory cells in which multiple memory levels are formed above a single substrate, such as a wafer. Memory array 202 may include any type of non-volatile memory that are monolithically formed in one or more physical levels of memory cells having an active area disposed above a silicon (or other type of) substrate. In an example, the non-volatile memory cells comprise vertical NAND strings with charge-trapping layers.

In another embodiment, memory array 202 includes a two-dimensional memory array of non-volatile memory cells. In an example, the non-volatile memory cells are NAND flash memory cells utilizing floating gates. Other types of memory cells (e.g., NOR-type flash memory) also can be used.

The exact type of memory array architecture or memory cell included in memory array 202 is not limited to the examples above. Many different types of memory array architectures or memory technologies can be used to form memory array 202. No particular non-volatile memory technology is required for purposes of the new claimed embodiments proposed herein.

Other examples of suitable technologies for memory cells of memory array 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of memory array 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell.

A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells.

In an embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb₂Te₃ super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory array, memory construction or material composition, but covers many relevant memory array structures within the spirit and scope of the technology as described herein and as understood by one of ordinary skill in the art.

The elements of FIG. 2A can be grouped into two parts: (1) memory array 202 and (2) peripheral circuitry, which includes all of the other components depicted in FIG. 2A. An important characteristic of a memory circuit is its capacity, which can be increased by increasing the area of the memory die of storage system 100 that is given over to memory array 202. However, this reduces the area of the memory die available for the peripheral circuitry. This can place quite severe restrictions on these elements of the peripheral circuitry.

For example, the need to fit sense amplifier circuits within the available area can be a significant restriction on sense amplifier design architectures. With respect to system control logic 208, reduced availability of area can limit the available functions that can be implemented on-chip. Consequently, a basic trade-off in the design of a memory die for storage system 100 is the amount of area to devote to memory array 202 and the amount of area to devote to the peripheral circuitry.

Another area in which memory array 202 and the peripheral circuitry are often at odds is in the processing involved in forming these regions, since these regions often involve differing processing technologies and the trade-off in having differing technologies on a single die. For example, when memory array 202 is NAND flash, this is an NMOS structure, while the peripheral circuitry is often CMOS based.

For example, elements such as sense amplifier circuits, charge pumps, logic elements in a state machine, and other peripheral circuitry in system control logic 208 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed die that are then bonded together. More specifically, memory array 202 can be formed on one die (referred to as the memory die) and some or all of the peripheral circuitry elements, including one or more control circuits, can be formed on a separate die (referred to as the control die).

For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array.

The two die can then be bonded together in a bonded multi-die memory circuit, with the array on one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of an embodiment of an integrated memory assembly 240. One or more integrated memory assemblies 240 may be used to implement non-volatile memory 106 of storage system 100.

Integrated memory assembly 240 includes two types of semiconductor die (or more succinctly, “die”). Memory die 242 includes memory array 202 that includes non-volatile memory cells. Control die 244 includes row control circuitry 204, system control logic 208, and column control circuitry 216 (as described above). In some embodiments, control die 244 is configured to connect to memory array 202 in memory die 242. In some embodiments, memory die 242 and control die 244 are bonded together.

FIG. 2B shows an example of the peripheral circuitry, including control circuits, formed in a peripheral circuit or control die 244 coupled to memory array 202 formed in memory die 242. Common components are labelled similarly to FIG. 2A. System control logic 208, row control circuitry 204, and column control circuitry 216 are located in control die 244. In some embodiments, all or a portion of column control circuitry 216 and all or a portion of row control circuitry 204 are located on memory die 242. In some embodiments, some of the circuitry in system control logic 208 is located on memory die 242.

Row control circuitry 204, system control logic 208, and column control circuitry 216 may be formed by a common process (e.g., CMOS process), so that adding elements and functions, such as ECC, more typically found on a memory controller 104 may require few or no additional process steps (i.e., the same process steps used to fabricate controller 104 also may be used to fabricate row control circuitry 204, system control logic 208, and column control circuitry 216).

Thus, while moving such circuits from a die such as memory 242 may reduce the number of steps needed to fabricate such a die, adding such circuits to a die such as control die 244 may not require many additional process steps. Control die 244 also could be referred to as a CMOS die, due to the use of CMOS technology to implement some or all of row control circuitry 204, system control logic 208, and column control circuitry 216.

FIG. 2B shows column control circuitry 216 including sense block 218 on control die 244 coupled to memory array 202 on memory die 242 through electrical paths 220. For example, electrical paths 220 may provide electrical connection between column decoder 222, driver circuitry 224, and block select 226 and bit lines of memory array 202.

Electrical paths may extend from column control circuitry 216 in control die 244 through pads on control die 244 that are bonded to corresponding pads of the memory die 242, which are connected to bit lines of memory array 202. Each bit line of memory array 202 may have a corresponding electrical path 220, including a pair of bond pads, which connects to column control circuitry 216.

Similarly, row control circuitry 204, including row decoder 210, array drivers 212, and block select 214 are coupled to memory array 202 through electrical paths 206. Each electrical path 206 may correspond to a word line, dummy word line, or select gate line. Additional electrical paths also may be provided between control die 244 and memory die 242.

For purposes of this document, the phrases “a control circuit” or “one or more control circuits” can include any one of or any combination of memory controller 104 (FIG. 1), all or a portion of row control circuitry 204, all or a portion of system control logic 208, all or a portion of column control circuitry 216, state machine 228 (FIGS. 2A-2B), MCU 230, a microcontroller, a microprocessor, and/or other similar functioned circuits.

A control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, there is more than one control die 244 and more than one memory die 242 in an integrated memory assembly 240. In some embodiments, integrated memory assembly 240 includes a stack of multiple control die 244 and multiple memory die 242.

FIG. 2C is a block diagram depicting an embodiment of sense block 218 of FIGS. 2A-2B. In an embodiment, sense block 218 is partitioned into one or more core portions, referred to as sense modules (e.g., SM0) or sense amplifiers, and a common portion, referred to as a managing circuit (e.g., MC0). In an embodiment, there is a separate sense module for each bit line and one common managing circuit for a set of sense modules, such as SM0, SM1, SM2 and SM3. Each of the sense modules in a group communicates with the associated managing circuit via a data bus 246. Thus, there are one or more managing circuits which communicate with the sense modules of a set of memory cells.

Each sense module SM0, SM1, SM2 and SM3 includes sense circuitry SC0, SC1, SC2 and SC3, respectively, that performs sensing by determining whether a conduction current in a connected bit line BL0, BL1, BL2 and BL3, respectively, is above or below a predetermined threshold voltage (verify voltage).

Each sense module SM0, SM1, SM2 and SM3 also includes a bit line latch BLL0, BLL1, BLL2 and BLL3, respectively, that is used to set a voltage condition on the connected bit line. For example, during a programming operation, a predetermined state latched in a bit line latch will result in the connected bit line being pulled to a lockout state (e.g., 1.5-3 V), a slow programming state (e.g., 0.5-1 V) or a normal programming state (e.g., 0 V).

Managing circuit MC0 includes a data latch processor 248, data latches 250 including four example sets of data latches 250(0), 250(1), 250(2) and 250(3) and an I/O interface 252 coupled between the sets of data latches 250 and lines 254. In this example, each set of data latches 250 is associated with one of the bit lines. For example, data latches 250(0) are associated with bit line BL0, data latches 250(1) are associated with bit line BL1, data latches 250(2) are associated with bit line BL2, and data latches 250(3) are associated with bit line BL3.

Each set of data latches includes data latches identified by LDL 256, MDL 258, and UDL260, in this embodiment. LDL 256 stores a bit for a lower page of write data, MDL 258 stores a bit for a middle page of write data, and UDL 260 stores a bit for an upper page of write data, in a memory which stores three bits of data in each memory cell. Note that there may be one set of such latches associated with each bit line. Data latches 250 also may be used to store data read from the non-volatile memory cells.

Additional or fewer data latches per set could be used as well. For example, in a two-bit per memory cell implementation, the MDL data latch for the middle page of data is not needed. A four-bit per memory cell implementation can use LDL, LMDL (lower-middle page), UMDL (upper-middle page), and UDL latches. The techniques provided herein are meant to encompass such variations.

Data latch processor 248 performs computations during reading and programming. For reading, data latch processor 248 determines the data state stored in the sensed memory cell and stores the data in the set of data latches. For full programming and refresh programming, data latch processor 248 reads the latches to determine the data state which is to be written to a memory cell.

During reading, the operation of the system is under the control of MCU 230 which controls the supply of different control gate voltages to the addressed memory cell. As it steps through the various predefined control gate voltages corresponding to the various memory states supported by the memory, the sense module may trip at one of these voltages and a corresponding output will be provided from the sense module to data latch processor 248 via data bus 246. At that point, data latch processor 248 determines the memory state by considering the tripping event(s) of the sense module and the information about the applied control gate voltage from MCU 230 via input lines 262.

Data latch processor 248 then computes a binary encoding for the memory state and stores the resultant data bits into the data latches 250. For example, the memory state for a memory cell associated with bit line BL0 may be stored in data latches 250(0), etc. Herein, a “memory state” also may be referred to as a “data state.” In another embodiment of the managing circuit MC0, the bit line latch serves both as a latch for latching the output of the sense module and also as a bit line latch as described above.

In an embodiment, MCU 230 executes instructions to control data latch processor 248 to determine a data state (described in more detail below) of memory cells. The data state may be defined by a range of some physical parameter including, but not limited to, transistor threshold voltage, resistance, or current. Thus, to determine a data state means to determine what range of a certain physical parameter a memory cell is in.

In an embodiment, MCU 230 executes instructions to control data latch processor 248 to determine whether a memory cell conducts a current in response to voltages applied to the memory cell. In an embodiment, MCU 230 executes instructions to control data latch processor 248 to determine whether the threshold voltage of a memory cell is above or below a reference voltage applied to the memory cell.

During program or verify operations, the data to be programmed (write data) are stored in data latches 250 from lines 254, in the LDL, MDL, and UDL data latches. For example, the data to be programmed in a selected memory cell associated with bit line BL0 may be stored in data latches 250(0), the data to be programmed in a selected memory cell associated with bit line BL1 may be stored in data latches 250(1), etc.

The programming operation, under the control of MCU 230, includes a series of programming voltage pulses applied to the control gates of the addressed memory cells. Each programming voltage is followed by a read back (verify test) to determine if the memory cell has been programmed to the desired memory state.

In some cases, data latch processor 248 monitors the read back memory state relative to the desired memory state. When the two states agree, data latch processor 248 sets the bit line latch to cause the bit line to be pulled to a state designating program inhibit (e.g., 2 3V). This inhibits the memory cell coupled to the bit line from further programming even if programming voltages appear on its control gate. In other embodiments, data latch processor 248 initially loads the bit line latch, and the sense circuitry sets the bit line latch to an inhibit value during the verify process.

Each set of data latches 250 may be implemented as a stack of data latches for each sense module. In some implementations, the data latches are implemented as a shift register so that the parallel data stored therein is converted to serial data for lines 254, and vice versa. All data latches corresponding to the read/write block of memory cells can be linked together to form a block shift register so that a block of data can be input or output by serial transfer. In particular, the bank of read/write modules is adapted so that each of its set of data latches will shift data in to or out of the data bus in sequence as if they are part of a shift register for the entire read/write block.

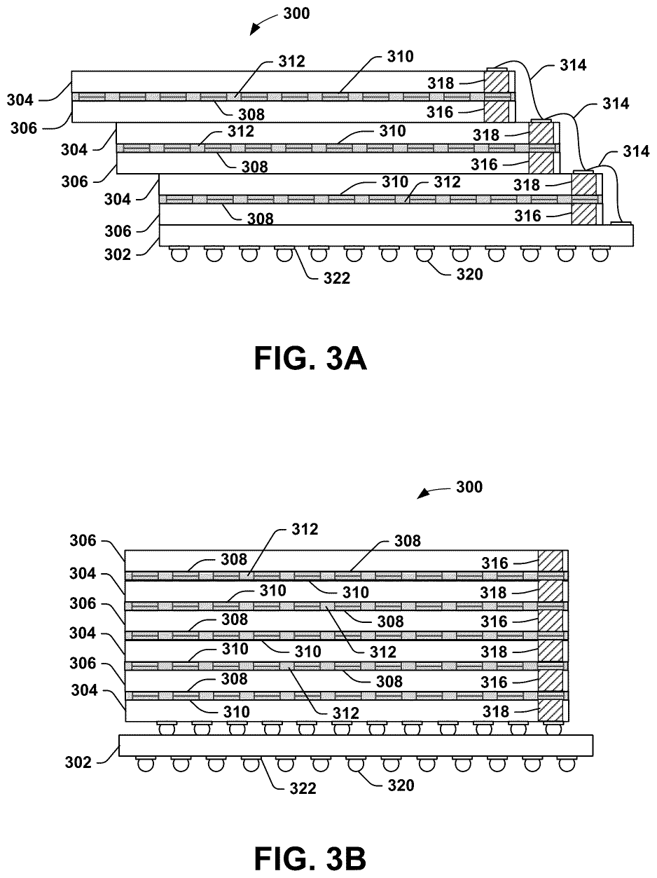

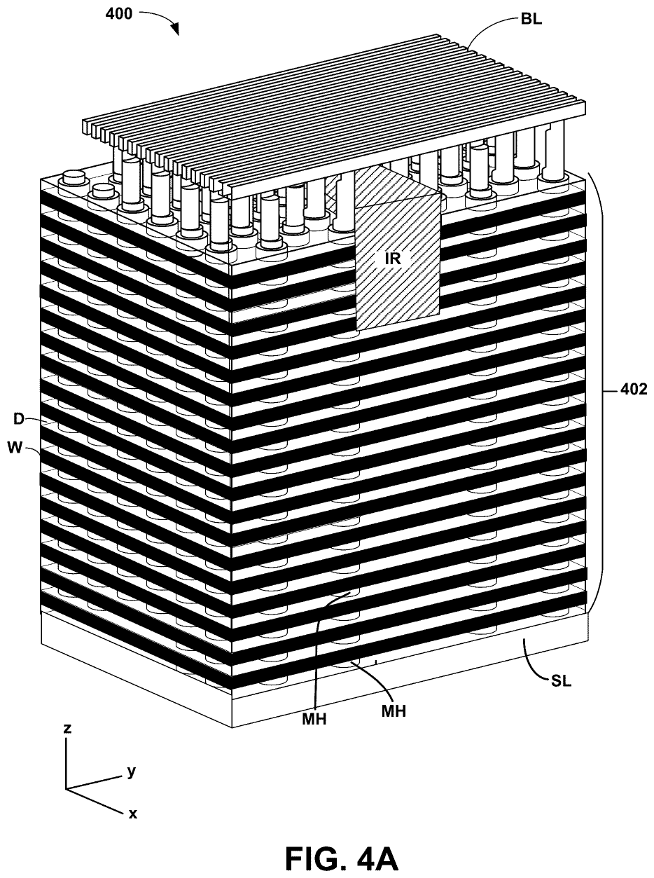

FIG. 3A depicts a side view of an embodiment of an integrated memory assembly 300 stacked on a substrate 302 (e.g., a stack including control die 304 and memory die 306). Integrated memory assembly 300 has three control die 304 and three memory die 306. In some embodiments, there are more than three memory die 306 and more than three control die 304.

Each control die 304 is affixed (e.g., bonded) to at least one memory die 306. Some bond pads 308/310 are depicted, although there may be many more bond pads. A space between two die 306, 304 that are bonded together is filled with a solid layer 312, which may be formed from epoxy or other resin or polymer. Solid layer 312 protects the electrical connections between die 304, 306, and further secures the die together. Various materials may be used as solid layer 312, but in embodiments, solid layer 312 may be Hysol epoxy resin from Henkel Corp., having offices in California, USA.

Integrated memory assembly 300 may for example be stacked with a stepped offset, leaving the bond pads at each level uncovered and accessible from above. Wire bonds 314 connected to the bond pads connect control die 304 to substrate 302. A number of such wire bonds may be formed across the width of each control die 304 (i.e., into the page of FIG. 3A).

A memory die through silicon via (TSV) 316 may be used to route signals through each memory die 306. A control die TSV 318 may be used to route signals through each control die 304. TSVs 316, 318 may be formed before, during or after formation of the integrated circuits in semiconductor die 306, 304. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 320 optionally may be affixed to contact pads 322 on a lower surface of substrate 302. Solder balls 320 may be used to couple integrated memory assembly 300 electrically and mechanically to a host device such as a printed circuit board. Solder balls 320 may be omitted where integrated memory assembly 300 is to be used as a land grid array package. Solder balls 320 may form a part of an interface between integrated memory assembly 300 and memory controller 104 (FIG. 1).

FIG. 3B depicts a side view of another embodiment of an integrated memory assembly 300 stacked on a substrate 302. Integrated memory assembly 300 of FIG. 3B has three control die 304 and three memory die 306. In some embodiments, there are many more than three memory die 306 and many more than three control die 304. In this example, each control die 304 is bonded to at least one memory die 306. Optionally, a control die 304 may be bonded to two or more memory die 306.

Some bond pads 308, 310 are depicted. There may be many more bond pads. A space between two die 306, 304 that are bonded together is filled with a solid layer 312, which may be formed from epoxy or other resin or polymer. In contrast to the example in FIG. 3A, integrated memory assembly 300 of FIG. 3B does not have a stepped offset. A memory die TSV 316 may be used to route signals through each memory die 306. A control die TSV 318 may be used to route signals through each control die 304.

As has been briefly discussed above, control die 304 and memory die 306 may be bonded together. Bond pads on each control die 304 and each memory die 306 may be used to bond the two die together. In some embodiments, the bond pads are bonded directly to each other, without solder or other added material, in a so-called Cu-to-Cu bonding process.

In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension.

Such bonds may be formed at room temperature, though heat also may be applied. In embodiments using cu-to-cu bonding, the bond pads may be about 5 μm square and spaced from each other with a pitch of 5 μm to 5 μm. Although this process is referred to herein as cu-to-cu bonding, this term also may apply even where the bond pads are formed of materials other than copper.

When the area of bond pads is small, it may be difficult to bond the semiconductor die together. The size of and pitch between bond pads may be further reduced by providing a film layer on the surfaces of the semiconductor die including the bond pads. The film layer is provided around the bond pads. When the die are brought together, the bond pads may bond to each other, and the film layers on the respective die may bond to each other.

Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of control die 304 and memory die 306. Where no such film is initially provided, a space between the die may be under filled with an epoxy or other resin or polymer. The under-fill material may be applied as a liquid which then hardens into a solid layer. This under-fill step protects the electrical connections between control die 304 and memory die 306, and further secures the die together. Various materials may be used as under-fill material, such as Hysol epoxy resin from Henkel Corp., having offices in California, USA.

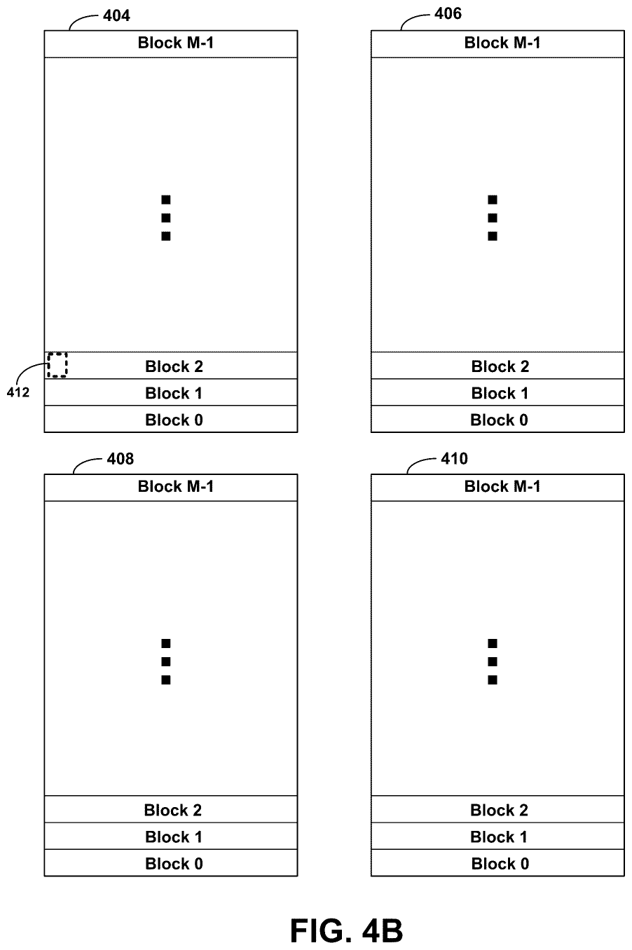

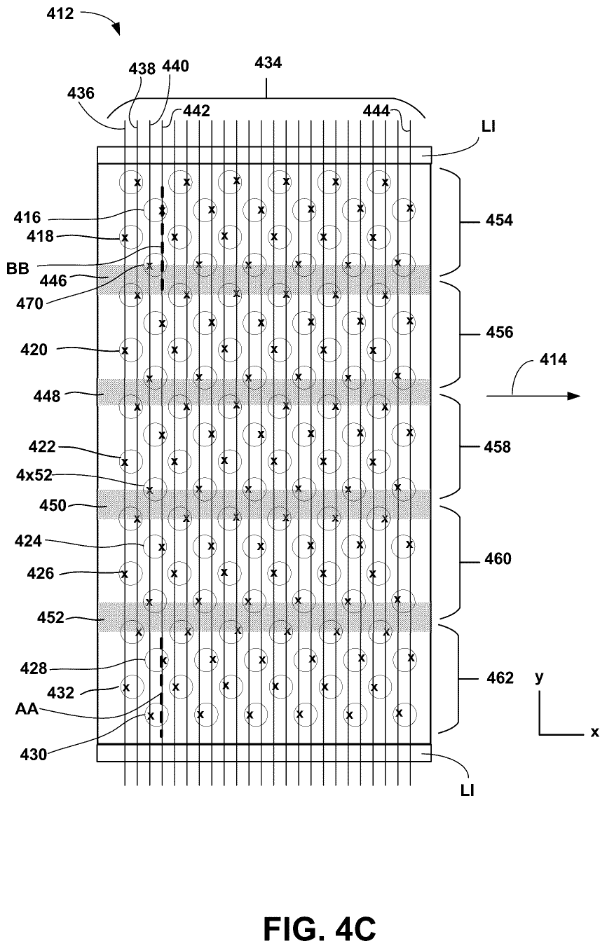

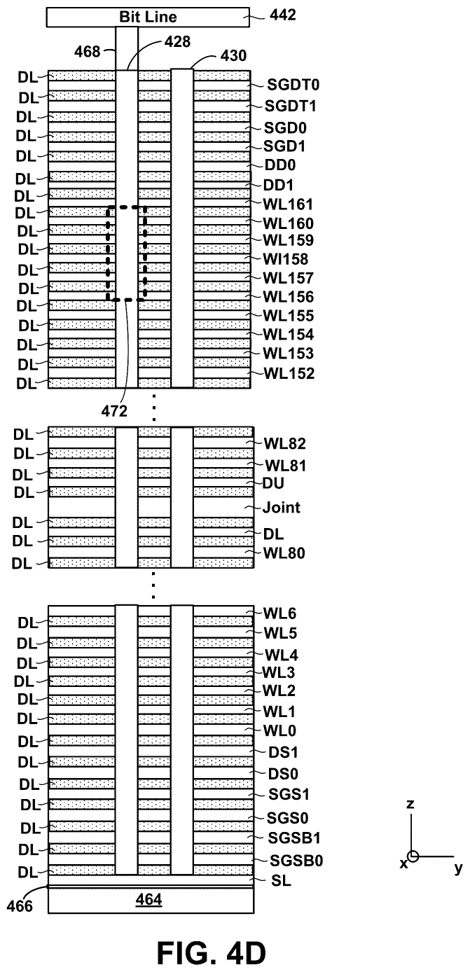

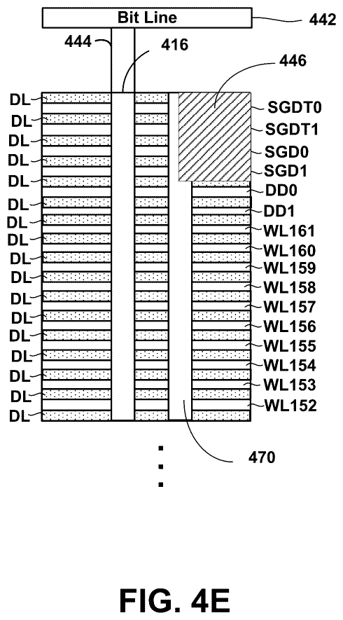

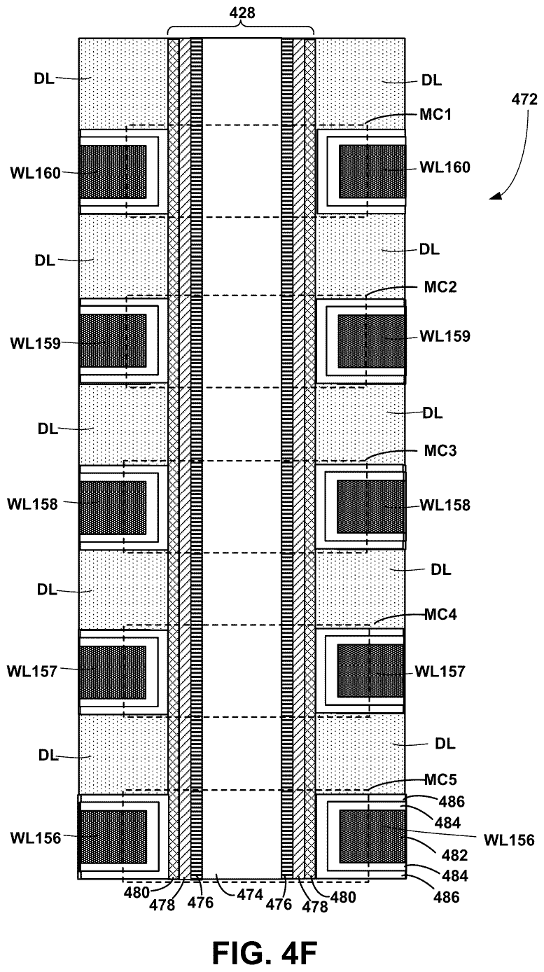

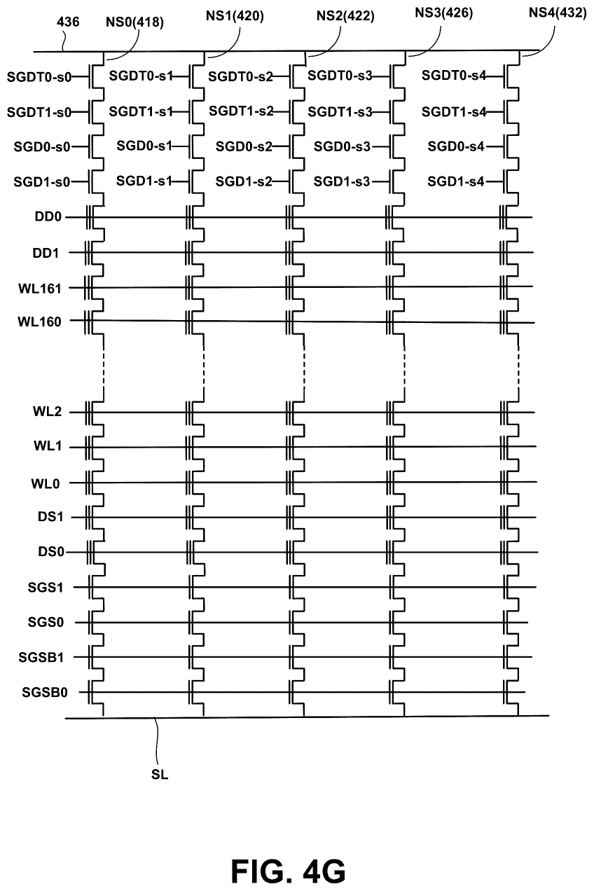

FIG. 4A is a perspective view of a portion of one example embodiment of a monolithic three dimensional memory array/structure included in memory array 202, which includes a plurality non-volatile memory cells arranged as vertical NAND strings. For example, FIG. 4A shows a portion 400 of one block of memory.

The structure depicted includes a set of bit lines BL positioned above a stack 402 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements.

As will be explained below, in an embodiment the alternating dielectric layers and conductive layers are divided into four or five (or a different number of) regions by isolation regions IR. FIG. 4A shows one isolation region IR separating two regions. Below the alternating dielectric layers and word line layers is a source line layer SL. Memory holes are formed in the stack of alternating dielectric layers and conductive layers.

For example, one of the memory holes is marked as MH. Note that in FIG. 4A, the dielectric layers are depicted as see-through so that the reader can see the memory holes positioned in the stack of alternating dielectric layers and conductive layers. In an embodiment, NAND strings are formed by filling the memory hole with materials including a charge-trapping material to create a vertical column of memory cells.

Each memory cell can store one or more bits of data. Thus, the non-volatile memory cells are arranged in memory holes. More details of the three dimensional monolithic memory array that comprises memory array 202 is provided below.

FIG. 4B is a block diagram explaining one example organization of memory array 202, which is divided into four planes 404, 406, 408 and 410. Each plane is then divided into M blocks. In an example, each plane has about 2000 blocks. However, different numbers of blocks and planes can also be used.

In an embodiment, a block of memory cells is a unit of erase. That is, all memory cells of a block are erased together. In other embodiments, blocks can be divided into sub-blocks and the sub-blocks can be the unit of erase. Memory cells also can be grouped into blocks for other reasons, such as to organize the memory array to enable the signaling and selection circuits.

In some embodiments, a block represents a groups of connected memory cells as the memory cells of a block share a common set of word lines. For example, the word lines for a block are all connected to all of the vertical NAND strings for that block. Although FIG. 4B shows four planes, more or less than four planes can be implemented. In some embodiments, memory array 202 includes eight planes.

Each block typically is divided into one or more pages. In an embodiment, a page is a unit of programming/writing and a unit of reading. Other units of programming also can be used. In an embodiment, one or more pages of data are typically stored in one row of memory cells. For example, one or more pages of data may be stored in memory cells connected to a common word line. In an embodiment, a page includes data stored in all memory cells connected to a common word line.

FIGS. 4C-4G depict an example three dimensional (“3D”) NAND structure that corresponds to the structure of FIG. 4A and can be used to implement memory array 202 of FIGS. 2A and 2B. FIG. 4C is a block diagram depicting a top view of a portion 412 of Block 2 of plane 404. As can be seen from FIG. 4C, the block depicted in FIG. 4C extends in the direction of 414. In an embodiment, the memory array has many layers. However, FIG. 4C only shows the top layer.

FIG. 4C depicts a plurality of circles that represent the memory holes, which are also referred to as vertical columns. Each of the memory holes/vertical columns include multiple select transistors (also referred to as a select gate or selection gate) and multiple memory cells. In an embodiment, each memory hole/vertical column implements a NAND string. For example, FIG. 4C labels a subset of the memory holes/vertical columns/NAND strings 416, 418, 420. 422, 424, 426, 428, 430 and 432.

FIG. 4C also depicts a set of bit lines 434, including bit lines 436, 438, 440, 442, . . . 444. FIG. 4C shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 436 is connected to memory holes/vertical columns 418, 420, 422, 426 and 432.

The block depicted in FIG. 4C includes a set of isolation regions 446, 448, 450 and 452, which are formed of SiO₂. However, other dielectric materials also can be used. Isolation regions 446, 448, 450 and 452 serve to divide the top layers of the block into five regions. For example, the top layer depicted in FIG. 4C is divided into regions 454, 456, 458, 460 and 462.

In an embodiment, the isolation regions only divide the layers used to implement select gates so that NAND strings in different regions can be independently selected. In an example implementation, a bit line connects to one memory hole/vertical column/NAND string in each of regions 454, 456, 458, 460 and 462. In that implementation, each block has twenty four rows of active columns and each bit line connects to five rows in each block.

In an embodiment, all of the five memory holes/vertical columns/NAND strings connected to a common bit line are connected to the same set of word lines; therefore, the system uses the drain side selection lines to choose one (or another subset) of the five to be subjected to a memory operation (program, verify, read, and/or erase).

FIG. 4C also shows Line Interconnects LI, which are metal connections to the source line SL from above the memory array. Line Interconnects LI are positioned adjacent regions 454 and 462.

Although FIG. 4C shows each region 454, 456, 458, 460 and 462 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block.

FIG. 4C also shows the memory holes/vertical columns being staggered. In other embodiments, different patterns of staggering can be used. In some embodiments, the memory holes/vertical columns are not staggered.

FIG. 4D depicts a portion of one embodiment of a three dimensional memory array 202 showing a cross-sectional view along line AA of FIG. 4C. This cross sectional view cuts through memory holes/vertical columns (NAND strings) 428 and 430 of region 462 (see FIG. 4C).

The structure of FIG. 4D includes two drain side select layers SGD0 and SGD, the source side select layers SGS0 and SGS1, two drain side GIDL generation transistor layers SGDT0 and SGDT1, two source side GIDL generation transistor layers SGSB0 and SGSB1, two drain side dummy word line layers DD0 and DD1, two source side dummy word line layers DS0 and DS1, dummy word line layers DU and DL, one hundred and sixty two word line layers WL0-WL161 for connecting to data memory cells, and dielectric layers DL.

Other embodiments can implement more or less than the numbers described above for FIG. 4D. In an embodiment, SGD0 and SGD1 are connected together; and SGS0 and SGS1 are connected together. In other embodiments, more or less number of SGDs (greater or lesser than two) are connected together, and more or less number of SGS devices (greater or lesser than two) connected together.

In an embodiment, erasing the memory cells is performed using gate induced drain leakage (GIDL), which includes generating charge carriers at the GIDL generation transistors such that the carriers get injected into the charge trapping layers of the NAND strings to change threshold voltage of the memory cells. FIG. 4D shows two GIDL generation transistors at each end of the NAND string; however, in other embodiments there are more or less than three.

Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

FIG. 4D shows two GIDL generation transistors at each end of the NAND string. It is likely that charge carriers are only generated by GIDL at one of the two GIDL generation transistors at each end of the NAND string. Based on process variances during manufacturing, it is likely that one of the two GIDL generation transistors at an end of the NAND string is best suited for GIDL.

For example, the GIDL generation transistors have an abrupt PN junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

Memory holes/Vertical columns 428 and 430 are depicted protruding through the drain side select layers, source side select layers, dummy word line layers, GIDL generation transistor layers and word line layers. In an embodiment, each memory hole/vertical column comprises a vertical NAND string. Below the memory holes/vertical columns and the layers listed below is substrate 464, an insulating film 466 on the substrate, and source line SL. The NAND string of memory hole/vertical column 428 has a source end at a bottom of the stack and a drain end at a top of the stack. As in agreement with FIG. 4C, FIG. 4D show vertical memory hole/column 428 connected to bit line 442 via connector 468.

For ease of reference, drain side select layers, source side select layers, dummy word line layers, GIDL generation transistor layers and data word line layers collectively are referred to as conductive layers.

In an embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof.

In some embodiments, different conductive layers can be formed from different materials. Between conductive layers are dielectric layers DL. In an embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In an embodiment, the memory cells are arranged in NAND strings. The word line layers WL0-W161 connect to memory cells (also called data memory cells). Dummy word line layers connect to dummy memory cells.

A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4D shows that the memory array is implemented as a two tier architecture, with the tiers separated by a Joint area. In an embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In an embodiment, the Joint areas are made from the same materials as the word line layers. In other embodiments, there can no Joint area or there can be multiple Joint areas.

FIG. 4E depicts a portion of one embodiment of a three dimensional memory array 202 showing a cross-sectional view along line BB of FIG. 4C. This cross sectional view cuts through memory holes/vertical columns (NAND strings) 416 and 470 of region 454 (see FIG. 4C). FIG. 4E shows the same alternating conductive and dielectric layers as FIG. 4D.

FIG. 4E also shows isolation region 446. Isolation regions 446, 448, 450 and 452) occupy space that would have been used for a portion of the memory holes/vertical columns/NAND stings. For example, isolation region 446 occupies space that would have been used for a portion of memory hole/vertical column 470. More specifically, a portion (e.g., half the diameter) of vertical column 470 has been removed in layers SGDT0, SGDT1, SGD0, and SGD1 to accommodate isolation region 446.

Thus, while most of the vertical column 470 is cylindrical (with a circular cross section), the portion of vertical column 470 in layers SGDT0, SGDT1, SGD0, and SGD1 has a semi-circular cross section. In an embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 454, 456, 458, 460, and 462.

FIG. 4F depicts a cross sectional view of region 472 of FIG. 4D that includes a portion of memory hole/vertical column 428. In an embodiment, the memory holes/vertical columns are round. However, in other embodiments other shapes can be used. In an embodiment, memory hole/vertical column 428 includes an inner core layer 474 that is made of a dielectric, such as SiO₂. Other materials can also be used.

Surrounding inner core 474 is polysilicon channel 476. Materials other than polysilicon can also be used. Note that it is the channel 476 that connects to the bit line and the source line. Surrounding channel 476 is a tunneling dielectric 478. In an embodiment, tunneling dielectric 478 has an ONO structure. Surrounding tunneling dielectric 478 is charge trapping layer 480, such as (for example) Silicon Nitride. Other memory materials and structures can also be used. The technology described herein is not limited to any particular material or structure.

FIG. 4F depicts dielectric layers DL as well as word line layers WL160, WL159, WL158, WL157, and WL156. Each of the word line layers includes a word line region 482 surrounded by an aluminum oxide layer 484, which is surrounded by a blocking oxide layer 486. In other embodiments, the blocking oxide layer can be a vertical layer parallel and adjacent to charge trapping layer 480. The physical interaction of the word line layers with the vertical column forms the memory cells.

Thus, in an embodiment a memory cell includes channel 476, tunneling dielectric 478, charge trapping layer 480, blocking oxide layer 486, aluminum oxide layer 484 and word line region 482. For example, word line layer WL160 and a portion of memory hole/vertical column 428 comprise a memory cell MC1. Word line layer WL159 and a portion of memory hole/vertical column 428 comprise a memory cell MC2. Word line layer WL158 and a portion of memory hole/vertical column 428 comprise a memory cell MC3. Word line layer WL157 and a portion of memory hole/vertical column 428 comprise a memory cell MC4. Word line layer WL156 and a portion of memory hole/vertical column 428 comprise a memory cell MC5. In other architectures, a memory cell may have a different structure; however, the memory cell would still be the storage unit.

When a memory cell is programmed, electrons are stored in a portion of the charge trapping layer 480 which is associated with (e.g. in) the memory cell. These electrons are drawn into the charge trapping layer 480 from the channel 476, through the tunneling dielectric 478, in response to an appropriate voltage on word line region 482. The threshold voltage (Vth) of a memory cell is increased in proportion to the amount of stored charge.

In an embodiment, the programming is achieved through Fowler-Nordheim tunneling of the electrons into the charge trapping layer. During an erase operation, the electrons return to the channel or holes are injected into the charge trapping layer to recombine with electrons. In an embodiment, erasing is achieved using hole injection into the charge trapping layer via a physical mechanism such as GIDL.

FIG. 4G is a schematic diagram of a portion of the three dimensional memory array 202 depicted in in FIGS. 4B-4F. FIG. 4G shows physical data word lines WL0-WL161 running across the entire block. The structure of FIG. 4G corresponds to a portion 412 in Block 2 of FIG. 4B, including bit line 436. Within the block, in an embodiment, each bit line is connected to five NAND strings, one in each region of regions 454, 456, 458, 460, 462.

Thus, FIG. 4G shows bit line 436 connected to NAND string NS0 (which corresponds to memory hole/vertical column 418 of region 454), NAND string NS1 (which corresponds to memory hole/vertical column 420 of region 456), NAND string NS2 (which corresponds to vertical column 422 of region 458), NAND string NS3 (which corresponds to memory hole/vertical column 426 of region 460), and NAND string NS4 (which corresponds to memory hole/vertical column 432 of region 462).

Drain side select line/layer SGD0 is separated by isolation regions isolation regions 446, 448, 450 and 452 to form SGD0-s0, SGD0-s1, SGD0-s2, SGD0-s3 and SGD0-s4 in order to separately connect to and independently control regions 454, 456, 458, 460, 462.

Similarly, drain side select line/layer SGD1 is separated by isolation regions 446, 448, 450 and 452 to form SGD1-s0, SGD1-s1, SGD1-s2, SGD1-s3 and SGD1-s4 in order to separately connect to and independently control regions 454, 456, 458, 460, 462.

Drain side GIDL generation transistor control line/layer SGDT0 is separated by isolation regions 446, 448, 450 and 452 to form SGDT0-s0, SGDT0-s1, SGDT0-s2, SGDT0-s3 and SGDT0-s4 in order to separately connect to and independently control regions 454, 456, 458, 460, 462.

Drain side GIDL generation transistor control line/layer SGDT1 is separated by isolation regions 446, 448, 450 and 452 to form SGDT1-s0, SGDT1-s1, SGDT1-s2, SGDT1-s3 and SGDT1-s4 in order to separately connect to and independently control regions 454, 456, 458, 460, 462.

FIG. 4G only shows NAND strings connected to bit line 436. However, a full schematic of the block would show every bit line and five vertical NAND strings (that are in separate regions) connected to each bit line.

Although the example memories of FIGS. 4B-4G are three dimensional memory arrays that include vertical NAND strings with charge-trapping material, other (2D and 3D) memory arrays can also be used with the technology described herein.

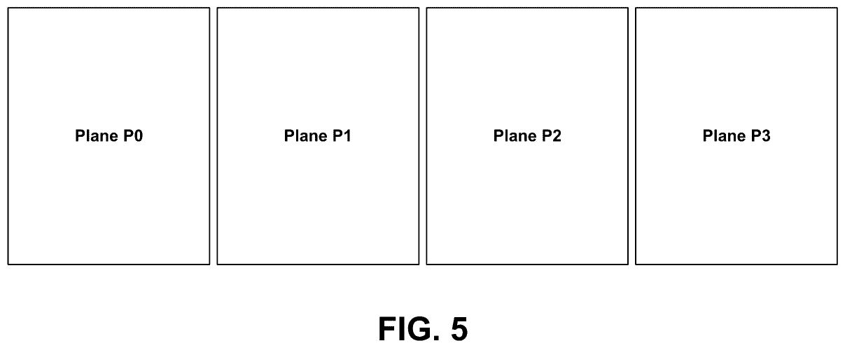

As described above, a memory array (such as memory array 202 of FIG. 2A) may include multiple planes, and each plane may operate in parallel. For example, FIG. 5 is a diagram depicting a memory array that includes four planes: P0, P1, P2 and P3. In an embodiment, each of planes P0, P1, P2 and P3 includes a physical page size. For example, the physical page size may be 4 kB/page. Other physical page sizes may be used.

The memory systems discussed above can be erased, programmed/written and read. At the end of a successful programming process (with verification), the threshold voltages of the memory cells should be within one or more distributions of threshold voltages for programmed memory cells or within a distribution of threshold voltages for erased memory cells, as appropriate.

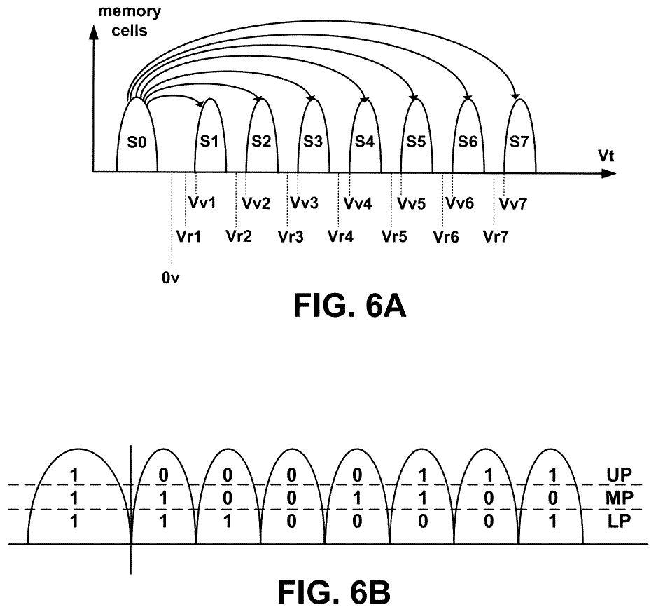

FIG. 6A illustrates example threshold voltage distributions for a memory cell array in which each memory cell stores three bits of data. Other embodiments, however, may use other data capacities per memory cell (e.g., such as one, two, four, or five bits of data per memory cell).

FIG. 6A shows eight threshold voltage distributions, corresponding to eight data states. The first threshold voltage distribution (data state) S0 represents memory cells that are erased. The other seven threshold voltage distributions (data states) S1-S7 represent memory cells that are programmed and, therefore, also are called programmed states. Each threshold voltage distribution (data state) corresponds to predetermined values for the set of data bits.

The specific relationship between the data programmed into the memory cell and the threshold voltage levels of the cell depends upon the data encoding scheme adopted for the cells. In an embodiment, data values are assigned to the threshold voltage ranges using a Gray code assignment so that if the threshold voltage of a memory erroneously shifts to its neighboring data state, only one bit will be affected. For example, FIG. 6B depicts an example data coding scheme for data states S0-S7 of FIG. 6A.

FIG. 6A also shows seven read reference voltages, Vr1, Vr2, Vr3, Vr4, Vr5, Vr6, and Vr7, for reading data from memory cells. By testing (e.g., performing sense operations) whether the threshold voltage of a given memory cell is above or below the seven read reference voltages, the system can determine a data state (e.g., S0, S1, S2, S3, . . . ) of each memory cell.

FIG. 6A also shows seven verify reference voltages, Vv1, Vv2, Vv3, Vv4, Vv5, Vv6, and Vv7. When programming memory cells to data state S1, the system tests whether those memory cells have a threshold voltage greater than or equal to Vv1. When programming memory cells to data state S2, the system tests whether the memory cells have threshold voltages greater than or equal to Vv2, and so on.

In an embodiment, known as full sequence programming, memory cells can be programmed from the erased data state S0 directly to any of the programmed data states S1-S7. For example, a population of memory cells to be programmed may first be erased so that all memory cells in the population are in erased data state S0. Then, a programming process is used to program memory cells directly into data states S1, S2, S3, S4, S5, S6, and/or S7.

For example, while some memory cells are being programmed from data state S0 to data state S1, other memory cells are being programmed from data state S0 to data state S2 and/or from data state S0 to data state S3, and so on. The arrows of FIG. 6A represent full sequence programming. The technology described herein also can be used with other types of programming in addition to full sequence programming (including, but not limited to, multiple stage/phase programming). In some embodiments, data states S1-S7 can overlap, and memory controller 104 may rely on ECC to identify the correct data being stored.

In an embodiment, when a block is subjected to an erase operation, all memory cells are moved to data state S0, the erased state. The proposed technology described herein can be used for embodiments in which each memory cell stores more or less than three bits of data per memory cell.

In the memory die described above, such as memory die 200 (FIG. 2A), memory die 242 (FIG. 2B) and memory die 306 (FIGS. 3A-3B), high voltages are needed to perform program and read operations, and these high voltages are generated by charge pumps on the memory die. For example, as described above, power control module 232 controls the power and voltages supplied to the rows and columns of memory array 202 during memory operations and may include charge pumps and regulator circuits for regulating voltages. During program and read operations, the charge pump output is coupled to unselected word lines of a block of memory cells selected for program/read operations.

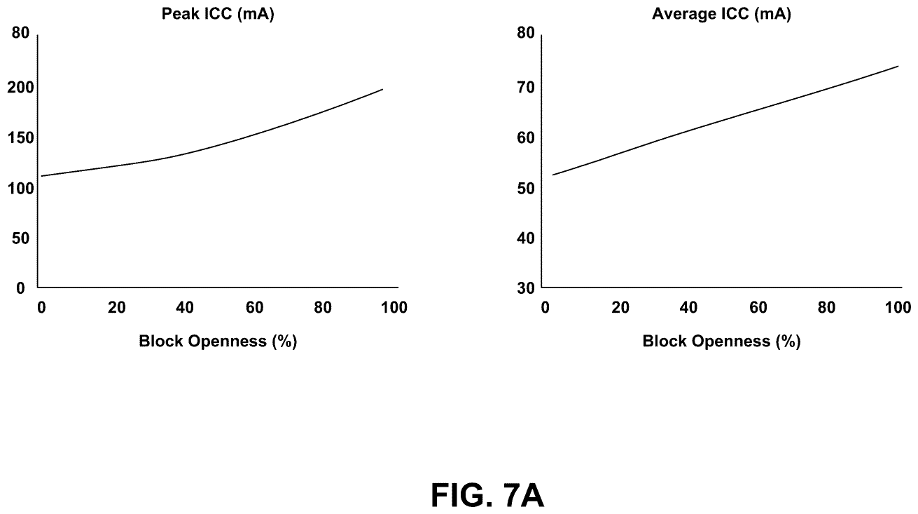

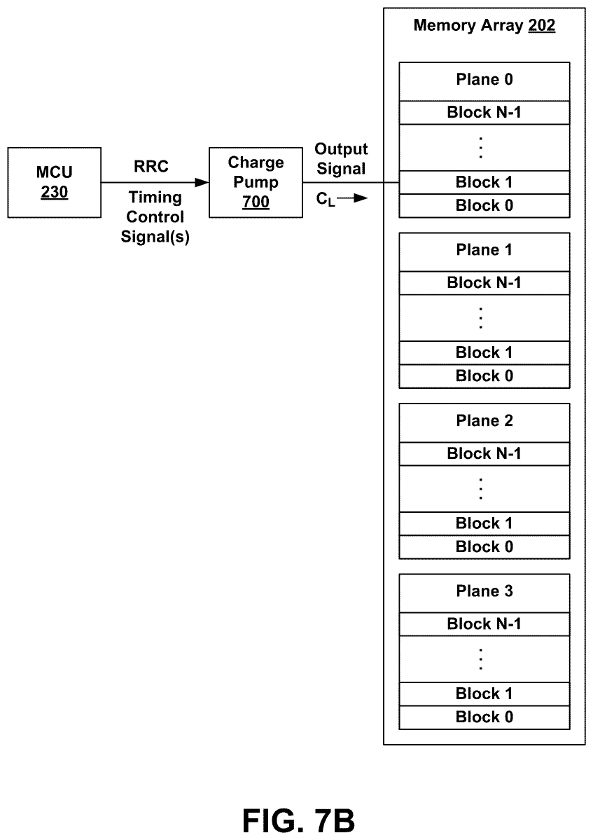

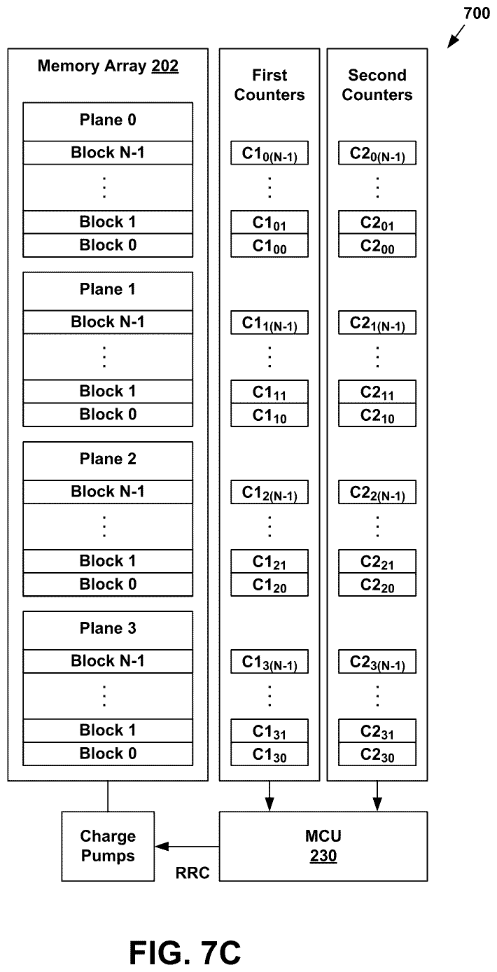

As a result, the charge pump sees a capacitive load at its output, and the capacitive load varies based on the number of programmed word lines and the data pattern written to the memory cells of the block. For example, FIG. 7A depicts diagrams of peak ICC and average ICC versus “block openness.” For example, of a block includes 100 word lines, and no word lines are programmed, the block openness=100%, if 50 word lines are programmed, the block openness=50%, if 100 word lines are programmed, block openness=0%, and so on. The example diagram indicates that as the block openness increases, peak and average ICC both increase.

Average ICC is directly proportional to the capacitive load seen by the charge pumps. In the example of FIG. 7A, average ICC increases by about 50% from a closed block (block openness=0%) to a fully open block (block openness=100%). This indicates that the capacitive load seen by the charge pumps keeps increasing (with a fixed voltage, pump control and ramp timing) as the number word lines that are in an erase state (i.e., unprogrammed) increases.

A similar effect relationship exists between the data pattern written to the memory cells of the block and the capacitive load seen by the charge pumps. In particular, for a three bit per cell memory cell, as the average data pattern of a block varies from state S1 to state S7, the capacitive load seen by the charge pumps increases.

As described above, during program and read operations on a block of memory cells, an output terminal of a charge pump output is coupled to unselected word lines in the block. FIG. 7B is a simplified diagram depicting a charge pump 700 having an output terminal coupled to unselected word lines (not shown separately) in a block of memory cells of memory array 202. For example, power control module 232 (FIGS. 2A-2B) many include one or more charge pumps 700 whose output terminals are coupled to blocks of memory cells of memory array 202.

In embodiments, charge pump 700 includes a timing control input terminal coupled to a timing control output of a digital engine (e.g., MCU 230 of FIGS. 2A-2B). In an embodiment, charge pump 700 generates an output signal (e.g., a voltage ramp) at the output terminal a ramp rate that is based on a signal at the timing control input terminal.

In an embodiment, MCU 230 provides a timing control signal to the timing control input terminal of charge pump 700 to control the timing of the output signal ramp of charge pump 700. In an embodiment, MCU 230 provides a fixed ramp rate control signal (referred to herein as “RRC”) to the timing control input terminal of charge pump 700 to cause charge pump 700 to generate an output signal at the output terminal that ramps at a fixed ramp rate from an initial voltage (e.g., 0V) to a final voltage (e.g., 20V) depending on the particular memory operation being performed.

During a memory operation (e.g., program and read) on a word line of a block of memory cells, the unselected word lines of the block appear as a capacitive load CL to the output of charge pump 700. In general, the fixed RRC is determined assuming worst case capacitive loading of charge pump 700. Using a fixed RRC impacts memory device performance. In particular, the rate at which a charge pump output ramps from the initial voltage to the final voltage directly impacts array programming time (tPROG) and array read time (tREAD).

As described above, however, the capacitive load seen by the charge pumps is not static, but instead varies based on the number of programmed word lines and the data pattern written to the memory cells of the block. Indeed, in many operating conditions the actual load capacitance will not be the worst-case load capacitance, and will be less than worst-case load capacitance. Nevertheless, many memory systems use a fixed RRC for all program and read operations regardless of actual capacitive loading conditions.

Technology is described for timing control for memory operations such as program and read operations. FIG. 7C is a simplified diagram of an embodiment of a memory system 700 that includes a memory array 202 that includes multiple planes (e.g., Plane 0, Plane 1, Plane 2 and Plane 3), each plane including multiple blocks (e.g., N blocks) of memory cells.

In an embodiment, for each block of memory cells in a memory array a corresponding first counter C1 is maintained. For example, in Plane 0, Block 0 has a corresponding first counter C1₀₀, Block 1 has a corresponding first counter C1₀₁, . . . , Block N−1 has a corresponding first counter C_{10(N-1)}, in Plane 1, Block 0 has a corresponding first counter C1₁₀, Block 1 has a corresponding first counter C1₁₁, . . . , Block N−1 has a corresponding first counter C1_{1(N-1)}, and so on.

In embodiments, the each first counter C1 has a value that equals a number of programmed word lines in the corresponding block of memory cells. In embodiments, during a program or read of a word line of a block of memory cells, MCU 230 uses the corresponding first counter C1 as a proxy for the relative capacitive load of the corresponding block as seen by the charge pump coupled to the block. In embodiments, during a program or read of a word line of a block of memory cells, MCU 230 uses the corresponding first counter C1 to adjust the ramp rate of the charge pump coupled to the unselected word lines of the block of memory cells.

In an embodiment, for each block of memory cells in a memory array a corresponding second counter C2 is maintained. For example, in Plane 0, Block 0 has a corresponding second counter C2₀₀, Block 1 has a corresponding second counter C2₀₁, . . . , Block N−1 has a corresponding second counter C2_{0(N-1)}, in Plane 1, Block 0 has a corresponding second counter C2₁₀, Block 1 has a corresponding second counter C2₁₁, . . . , Block N-1 has a corresponding second counter C2_{1(N-1)}, and so on.

In embodiments, each second counter C2 equals an average programmed state of programmed word lines in the corresponding block of memory cells. In embodiments, during a program or read of a word line of a block of memory cells, MCU 230 uses the corresponding second counter C2 as a proxy for the relative capacitive load of the corresponding block as seen by the charge pump coupled to the block. In embodiments, during a program or read of a word line of a block of memory cells, MCU 230 uses the corresponding second counter C2 to adjust the ramp rate of the charge pump coupled to the unselected word lines of the block of memory cells.

Without wanting to be bound by any particular theory, it is believed that the described technology may improve memory device performance and may reduce average array programming time tPROG and average array read time tREAD.

In an embodiment, first counter C1 tracks the number of programmed word lines in a block. So, for example, if a block has 100 word lines, a completely erased block has 0 programmed word lines. As each word line is programmed, counter C1 is incremented. So if ten word lines in the block have been programmed, first counter C1=10, if twenty word lines in the block have been programmed, first counter C1=20, and so on.

In an embodiment, first counter C1 updates based on the memory operation being performed in the corresponding block:

TABLE 1

| Memory Operation | First Counter C1 |
|---|---|
| Program a word line | C1 = C1 + 1 |
| Read a word line | No change |
| Erase the block | C1 = 0 |

That is, each time a word line in the block is programmed, corresponding first counter C1 is incremented by +1. Each time a word line is read, corresponding first counter C1 remains unchanged because a read operation does not impact the capacitive load of the block. Following an erase operation, corresponding first counter C1 is reset to 0 because all word lines in the block are erased at the same time.

In an embodiment, each block of memory cells includes 100 data word lines, and first counter C1 is an 7-bit counter (2⁷=128). In embodiments in which the number of data word lines per block is smaller than or greater than 100, the bit-length of first counter C1 may be less than or greater than 7. For example, if each block of memory cells includes 216 data word lines, first counter C1 is an 8-bit counter (2⁸=256).

In embodiments, first counters C1 may be implemented in hardware circuits in memory controller 104 (FIG. 1), system control logic 208 (FIGS. 2A-2B), or other similar circuitry. In other embodiments, first counters C1 may be implemented software or a combination of software and hardware in memory controller 104, system control logic 208, or other similar circuitry.

In an embodiment, a program or read operation programs or reads one word line (the selected word line) in a block at a time. All other word lines in the block are unselected word lines. So in the example above with 100 data word lines in a block, during a program or read operation there is one selected data word line and 99 unselected data word lines.

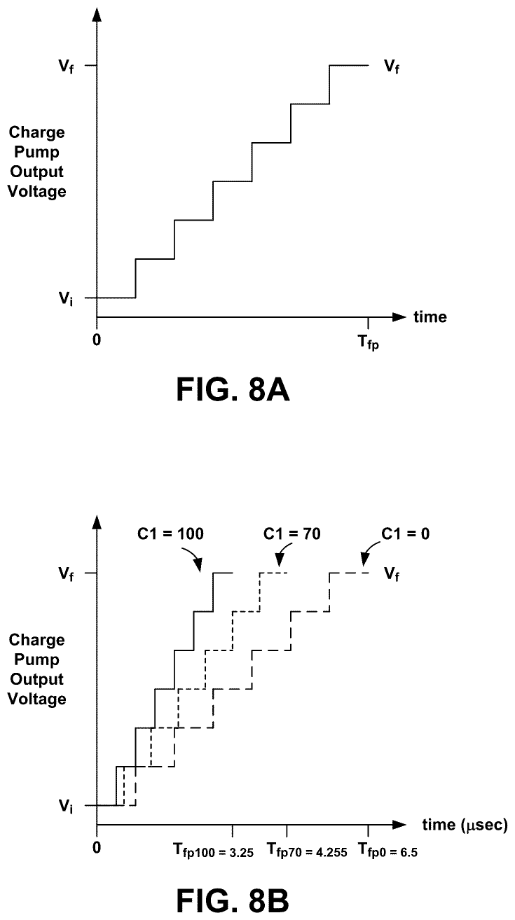

As described above, in an embodiment the unselected word lines are biased using a charge pump. In an embodiment, the charge pump outputs a staircase voltage ramp at a ramp rate RRC controlled by MCU 230 (FIGS. 2A-2B). For example, FIG. 8A depicts a graph of charge pump output voltage versus time in which the charge pump output ramps from an initial voltage time t=0 to a final voltage V_{f} at time t=T_{f}.

In embodiments, the charge pump is designed to have the ability to supply the specified output voltages at the RRC specified by MCU 230 regardless of the capacitive load of the unselected word lines that are driven by the charge pump. So, for example, at the fixed RRC the charge pump may reach the final output voltage V_{f} in 5.2 μsec for a read operation and in 6.5 μsec for a program operation. Thus, in FIG. 8A, for a read operation T_{f}=T_{fr}=5.2 usec, and for a program operation T_{f}=T_{fp}=6.5 usec.

In an embodiment, prior to programming a word line for a block, the value of the corresponding first counter C1 is used to determine an adjusted ramp rate control value R_{α}(C1):

$${R}_{α} ( C 1 ) = α 1 ( C 1 ) \times RRC \qquad ( 1 a )$$

$${α}_{1} ( C 1 ) = ( 1 - β \times \frac{C 1}{N} ) \qquad ( 1 b )$$

Where α₁(C1) is a first ramp rate scale factor, β is a capacitance scale factor and N=the total number of word lines in the block.

As described above, in the example depicted in FIG. 7A, average ICC increases by about 50% from a closed block (block openness=0%) to a fully open block (block openness=100%). Thus, assuming that the capacitive load of a block varies linearly with the number of programmed word lines, a value of capacitance scale factor β=0.5 may be used to compensate for the 50% capacitive load variation.

In an embodiment, MCU 230 (FIGS. 2A-2B) adjusts the timing of the charge pump to output a staircase voltage ramp at adjusted ramp rate α(C1)×RRC. For example, with β=0.5 and N=100, for a program operation the charge pump reaches the final output voltage V_{f} at time T_{fpC1}:

TABLE 2

| First Counter C1 | α₁(C1) | Tf_{pC1} (μsec) |
|---|---|---|
| 0 | 1.0000 | 6.5000 |
| 1 | 0.9950 | 6.4675 |
| 2 | 0.9900 | 6.4350 |
| 3 | 0.9850 | 6.4025 |
| 4 | 0.9800 | 6.3700 |
| 5 | 0.9750 | 6.3375 |
| 6 | 0.9700 | 6.3050 |
| . . . | . . . | . . . |
| 97 | 0.5150 | 3.3475 |
| 98 | 0.5100 | 3.3150 |
| 99 | 0.5050 | 3.2825 |
| 100 | 0.5000 | 3.2500 |

FIG. 8B depicts graphs of charge pump output voltage versus time for three different first counter C1 values for a program operation. In the illustrated example, for a first counter C1=0 (fully erased block), the adjusted ramp rate control value R_{α1} (0)=1.0×RRC, and the charge pump output voltage reaches the final output voltage V_{f} at T_{fp0}=6.5 μsec.

In contrast, for a first counter C1=100 (fully programmed block), the adjusted ramp rate control value R_{α1} (100)=0.5×RRC, and the charge pump output voltage reaches the final output voltage V_{f} at T_{fp100}=3.25 μsec. Similarly, for a first counter C1=70 (70% programmed block), the adjusted ramp rate control value R_{α1} (70)=0.35×RRC, and the charge pump output voltage reaches the final output voltage V_{f} at T_{fp100}=4.255 μsec.

As described above, for each block to be programmed or read, the corresponding first counter C1 serves as a proxy for the capacitive load of the block as seen by the charge pump coupled to the block, and MCU 230 adjusts a ramp rate of the charge pump based on corresponding first counter C1. Thus, in the above numerical example, a fully erased block (C1=0) corresponds to a maximum capacitive load coupled to the charge pump, and the adjusted ramp rate control value for the charge pump is set to the maximum value R_{α1} (0)=1.0×RRC.

In contrast, a completely programmed block (C1=100) corresponds to a minimum capacitive load coupled to the charge pump, and the adjusted ramp rate control value for the charge pump is set to the minimum value R_{α1} (100)=0.5×RRC. Between these two extremes, the capacitive load coupled to the charge pump is between the maximum and minimum values, and first counter C1 is used as a proxy for the capacitive load to set an adjusted ramp rate control value R_{α1} (C1) between the maximum and minimum values.

In an embodiment, prior to programming or reading a word line in a block, MCU 230 retrieves the corresponding first counter C1 value for the block and sets an adjusted ramp rate control value for the charge pump coupled to the block. For example, memory controller 104 may include a lookup table that includes ramp rate scale factor α₁ values and corresponding first counter C1 values, such as the example values in Table 2, above. In an embodiment, MCU 230 may extract from the lookup table the first ramp rate scale factor α₁ value that corresponds to the retrieved first counter C1 value. Other techniques also may be used.

Without wanting to be bound by any particular theory, it is believed that using the first counter C1 in this manner may improve memory device performance. For example, Table 3, below, lists example charge pump ramp time reductions for program (Δ_{TRP}) and read (Δ_{TRR}) operations in which T_{fp0}=6.5 μsec for program operations and T_{fr0}=5.2 μsec for read operations:

TABLE 3

| First Counter C1 | Δ_{TRP} (μsec) | Δ_{TRR} (μsec) |
|---|---|---|
| 0 | 0.0000 | 0.0000 |
| 1 | 0.0325 | 0.0260 |
| 2 | 0.0650 | 0.0520 |
| 3 | 0.0975 | 0.0780 |
| 4 | 0.1300 | 0.1040 |
| 5 | 0.1625 | 0.1300 |
| 6 | 0.1950 | 0.1560 |
| . . . | . . . | . . . |
| 97 | 3.1525 | 2.5220 |
| 98 | 3.1850 | 2.5480 |
| 99 | 3.2175 | 2.5740 |
| 100 | 3.2500 | 2.6000 |

Thus, as the number of programmed word line in a block increases, the charge pump ramp time reductions increase. The amount of time reduction will vary based on the actual use of the memory device (e.g., the amount of data written and the number of programmed word lines in each block). However, without wanting to be bound by any particular theory, it is believed that using the first counter C1 as described above may reduce average program and read times.

As described above, the capacitive load seen by the charge pumps varies not only based on the number of programmed word lines in a block, but also based on the data pattern written to the memory cells of the block, In particular, for a three bit per cell memory cell, as the average data pattern of a block varies from state S1 to state S7, the capacitive load seen by the charge pumps increases, with the lowest capacitive load at state S1 and the highest capacitive load at state S7.

In an embodiment, for each block of memory cells in a memory array a corresponding second counter C2 is maintained. In embodiments, the corresponding second counter C2 tracks an average programmed state of programmed word lines in the block of memory cells. In embodiments, the corresponding second counter C2 is used as a proxy for the relative capacitive load of the block as seen by the charge pump coupled to the block, and a ramp rate of the charge pump is adjusted based on corresponding first counter C1 and corresponding second counter C2.

In an embodiment, first counter C1 can be used for relatively coarse timing control based on the number of programmed word lines in a block, whereas second counter C2 can be used for finer control based on the average data values of programmed word lines in the block.

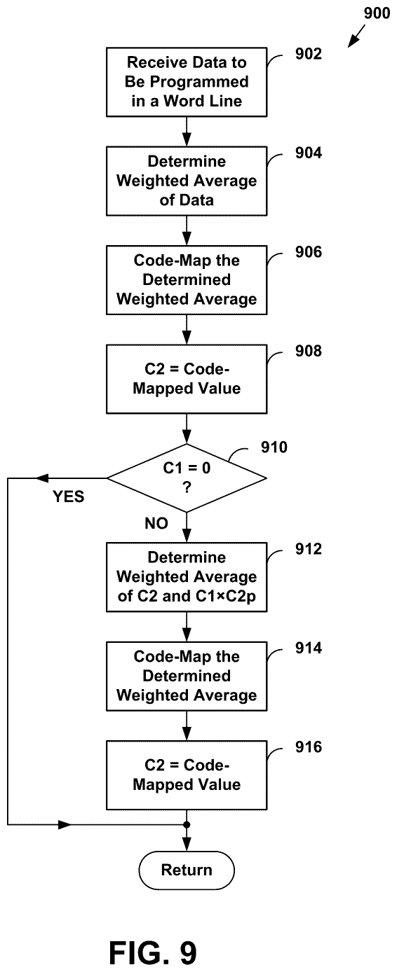

FIG. 9 is a flow diagram of a process 900 for determining second counter C2 values for programming operations for a block of memory cells. In embodiments, example process 900 may be implemented by one of or any combination of memory controller 104 (FIG. 1), all or a portion of row control circuitry 204, all or a portion of system control logic 208, all or a portion of column control circuitry 216, state machine 228 (FIGS. 2A-2B), MCU 230, a microcontroller, a microprocessor, and/or other similar functioned circuits.

At step 902, data to be programmed in a next word line to be programmed (referred to herein as “Next Word Line”) are received. For example, as described above and depicted in FIG. 2C, in a memory which stores three bits of data in each memory cell, LDL 256 stores a bit for a lower page of write data, MDL 258 stores a bit for a middle page of write data, and UDL 260 stores a bit for an upper page of write data.

At step 904, the weighted average of the Next Word Line data is determined. As described above, each block includes N word lines and in an example embodiment each word line has 16 KB of memory cells, each of which can be programmed with different data (e.g., programmed states S1-S7 depicted in FIGS. 6A-6B). Each state contributes differently to the capacitive load. Hence, it is required to normalize (find the weighted average) the impact of different states written on block to be able to improve the performance.

For 3 bit per cell memory, each state is represented by 3-page data (UP, MP & LP) as depicted in FIG. 6B. During programming, 16 KB data for each of 3-pages is passed through a data-path before moving into corresponding data-latches UDL 260, MDL 258 and LDL 256, respectively (FIG. 2C).

For decimal numbers, an average is calculated by adding the values and dividing by the number of entries. Calculating an average for 16 KB binary data would require a prohibitively large binary-adder. Instead, in an embodiment the weighted average is calculated as follows.

Because binary data consist of only 0s and 1s, the addition of 1s is equivalent to counting the number of 1s. For 16 KB data, a maximum possible count is 2¹⁷. Thus, in an embodiment a corresponding 20 bit counter may be used for each of UP, MP & LP. For example, count the total number of 1s in UP and store the result in a first 20-bit counter U20. Likewise, count the total number of 1s in MP and store the result in a second 20-bit counter M20. Similarly, count the total number of 1s in LP and store the result in a third 20-bit counter L20. Person of ordinary skill in the art will understand that other counter sizes may be used.

To provide a simple example, Table 4, below, includes example 16 bit Next Word Line data for UP, MP and LP for:

TABLE 4

| | #1 | #2 | #3 | #4 | #5 | #6 | #7 | #8 | #9 | #10 | #11 | #12 | #13 | #14 | #15 | #16 |
|---|---|---|---|---|---|---|---|---|---|---|---|---|---|---|---|---|
| UP | 0 | 1 | 1 | 1 | 0 | 0 | 1 | 0 | 0 | 0 | 1 | 0 | 1 | 1 | 0 | 0 |
| MP | 1 | 0 | 0 | 0 | 0 | 0 | 1 | 1 | 0 | 0 | 0 | 1 | 0 | 0 | 1 | 1 |
| LP | 0 | 1 | 0 | 1 | 1 | 0 | 0 | 1 | 1 | 0 | 0 | 1 | 0 | 1 | 0 | 1 |

In the above example, first counter U20=0111b, second counter M20=0110b, and third counter L20=1000b. Next, the three counters are “adjusted for place.” In particular, first counter U20 is the most significant bit (third bit=4s place), and hence is padded with two 0s on the least significant bit side. Second counter MP20 (second bit=2s place), and hence is padded with one 0 on the least significant bit side. Third counter LP20 (first bit=0s place) is not padded. Hence, after padding, the three counters have the values depicted in Table 5, below:

TABLE 5

| Counter | Value (binary) |
|---|---|
| UP20 | 11100 |
| MP20 | 01100 |
| LP20 | 01000 |

Next, the place-adjusted values in first counter U20, second counter M20, and third counter L20 are divided by the number of data entries (2¹⁷ for 16 KB entries) to obtain the average. For binary data, this is equivalent to right-shifting by 17 places. To avoid a LSB error in averaging, this may be accomplished by a first 15 bit right shift and a subsequent 2 bit right shift.

Continuing the 16 bit example from above, dividing by 16 (2⁴=16) is equivalent to right-shifting by 4 places. To avoid a LSB error in averaging, this may be accomplished by a first 2 bit right shift and a subsequent 2 bit right shift. After the initial 2 bit right shift, the data in first counter U20, second counter M20, and third counter L20 are depicted in Table 6, below:

TABLE 6

| Counter | Value (binary) |
|---|---|
| UP20 | 111 |
| MP20 | 011 |
| LP20 | 010 |

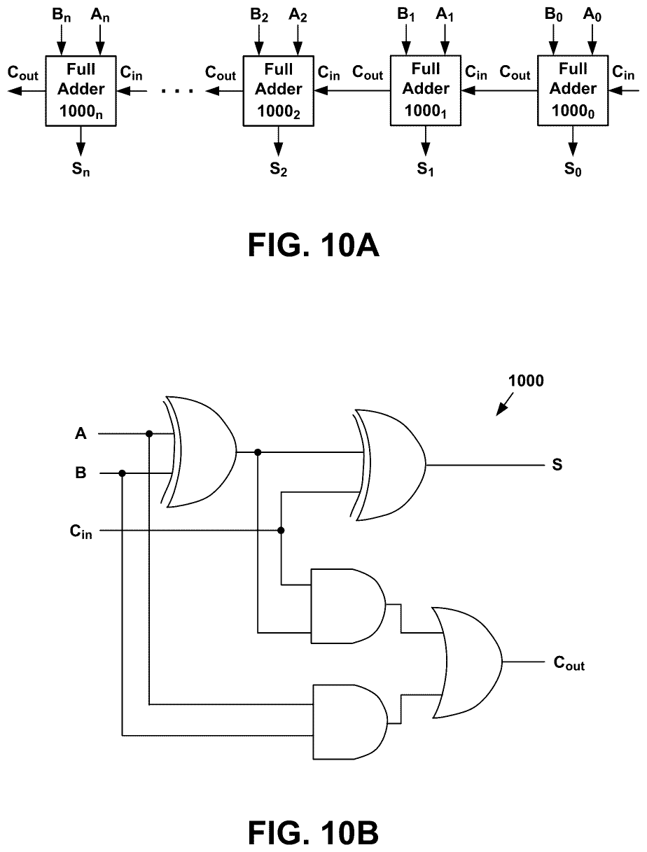

In an embodiment, the right-shifted values of first counter U20, second counter M20, and third counter L20 are added using a binary adder. For example, FIG. 10A is a simplified block diagram of an embodiment of an n-bit binary adder, which includes a cascade of n+1 full-adder circuits 1000₀, 1000₁, 1000₂, . . . , 1000ₙ, and FIG. 10B is a diagram of an embodiment of a full-adder circuit 1000. In an embodiment, each of full-adder circuits 1000₀, 1000₁, 1000₂, . . . , 1000ₙ of FIG. 10A is an implementation of full-adder circuit 1000 of FIG. 10B. Persons of ordinary skill in the art will understand that other full-adder circuits may be used.

Continuing the 16 bit Next Word Line example from above, using UP20 (111b), MP20 (011b) and LP20 (010b) as inputs to the binary adder, the resulting output is 1100b. Right shifting the result by the remaining 2 bits, the resulting determined weighted average is 011b. Without wanting to be bound by any particular theory, it is believed that all of the above calculations can be performed without impacting the time for data transfer, or can be performed in parallel while transferring data from input/output ports to a transfer data latch.

Referring again to FIG. 9, at step 906 the weighted average of the Next Word Line data determined at step 904 is code-mapped. In particular, the averaging calculations operate on the values of the data. However, the programmed states are represented by coded data (e.g., using the example data coding scheme of FIG. 6B for data states S0-S7). Thus, at step 906 the average of the Next Word Line data determined at step 904 is converted to the relevant state. Using the example coding scheme of FIG. 6B, the following conversion Table 7 may be used:

TABLE 7

| Determined Average Value (binary) | Code Mapped State Value (binary) |
|---|---|
| 000 | 011 (S1) |
| 001 | 001 (S2) |
| 010 | 000 (S3) |
| 011 | 010 (S4) |
| 100 | 110 (S5) |
| 101 | 100 (S6) |
| 110 | 101 (S7) |

Continuing the above example, the determined weighted average of the Next Word Line data is 011b. Using conversion Table 7, the code-mapped value is 010b, corresponding to state S4. Thus, the code-mapped weighted average of the Next Word Line data is 010b, corresponding to state S4.

Referring again to FIG. 9, at step 908 the code-mapped weighted average of the Next Word Line data determined at step 906 is saved as second counter C2.

At step 910, a determination is made whether the Next Word Line is the first word line in the block (i.e., C1=0). If C1=0, process 900 returns the code-mapped weighted average determined at step 908 as the second counter C2.

If other word lines in the block already have been programmed (i.e., C1>0), then the code-mapped weighted average determined at step 908 must be averaged with the average data values of the previously programmed word lines in the block. In an embodiment, at step 912 the previously determined second counter C2 value is fetched C1 number of times (to represent its weight already averaged by C1 number of times for previously programmed word lines in the block) and averaged with second counter C2 value determined at step 908 for the Next Word Line Data.

At step 914, the weighted average determined at step 912 average is code-mapped (e.g., as in step 906) and at step 916 the code-mapped weighted average determined at step 914 is saved as the corresponding second counter C2 for the block.

As described above, the corresponding second counter C2 is used as a proxy for the relative capacitive load of the block as seen by the charge pump coupled to the block, and a ramp rate of the charge pump is adjusted based on corresponding first counter C1 and corresponding second counter C2.

In an embodiment, prior to programming a word line for a block, the value of the corresponding first counter C1 and the value of the corresponding second counter C2 are used to determine an adjusted ramp rate control value R_{α2}(C1,C2):

R_{α2}(C1,C2)=α₂(C1,C2)×RRC (2a)

α₂(C1,C2)=α₁(C1+1)+Δ(C2)×(α₁(C1)−α₁(C1+1)) (2b)

where α₂(C1,C2) is a second ramp rate scale factor, and Δ(C2) is a scale factor based on the code-mapped weighted average data value of the block.

In an embodiment with seven programmed states, and assuming that the capacitive load of a block varies linearly programmed state, with state S1 having the lowest capacitive load and state S7 having the highest capacitive load, Table 8, below gives example values of scale factor Δ(C2):

TABLE 8

| C2 (binary) | Δ(C2) |
|---|---|
| 011 (S1) | 1/7 |
| 001 (S2) | 2/7 |
| 000 (S3) | 3/7 |
| 010 (S4) | 4/7 |
| 110 (S5) | 5/7 |
| 100 (S6) | 6/7 |
| 101 (S7) | 1 |

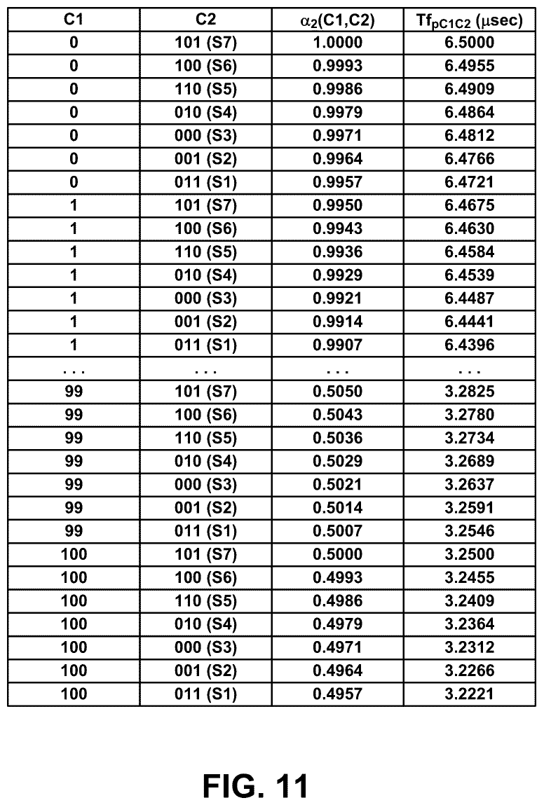

In an embodiment, MCU 230 (FIGS. 2A-2B) adjusts the timing of the charge pump to output a staircase voltage ramp at adjusted ramp rate α₂(C1,C2)×RRC. For example, FIG. 11 lists example values for a program operation in which the charge pump reaches the final output voltage V_{f} at time T_{fpC1C2}. Comparing FIG. 11 with Table 2, above, the effect of second counter C2 is a finer granularity in adjustments of ramp rate control. In example illustrated in FIG. 11, for each first counter C1 value, there are seven separate second ramp rate scale factors α₂(C1,C2).

For each block to be programmed or read, the corresponding first counter C1 and corresponding second counter C2 serve as a proxy for the capacitive load of the block as seen by the charge pump coupled to the block, and MCU 230 adjusts a ramp rate of the charge pump based on corresponding first counter C1 and corresponding second counter C2.

Thus, in example depicted in FIG. 11, a fully erased block (C1=0) with an average data value of 101 (S7) corresponds to a maximum capacitive load coupled to the charge pump, and the adjusted ramp rate control value for the charge pump is set to the maximum value R_{α2}(0, 101)=1.0×RRC.

In contrast, a completely programmed block (C1=100) with an average data value of 011 (S1) corresponds to a minimum capacitive load coupled to the charge pump, and the adjusted ramp rate control value for the charge pump is set to the minimum value R_{α2}(100,011)=0.4957×RRC. Between these two extremes, the capacitive load coupled to the charge pump is between the maximum and minimum values, and first counter C1 and second counter C2 are used as a proxy for the capacitive load to set an adjusted ramp rate control value R_{α2}(C1,C2) between the maximum and minimum values.

In an embodiment, prior to reading a word line in a block, MCU 230 retrieves the corresponding first counter C1 value and the corresponding second counter C2 for the block and sets an adjusted ramp rate control value for the charge pump coupled to the block. For example, memory controller 104 may include a lookup table that includes ramp rate scale factor α₂(C1,C2) values and corresponding first counter C1 values and corresponding second counter C2 values, such as the example values in FIG. 11. In an embodiment, MCU 230 may extract from the lookup table the second ramp rate scale factor α₂ value that corresponds to the retrieved first counter C1 value and second counter C2 value. Other techniques also may be used.

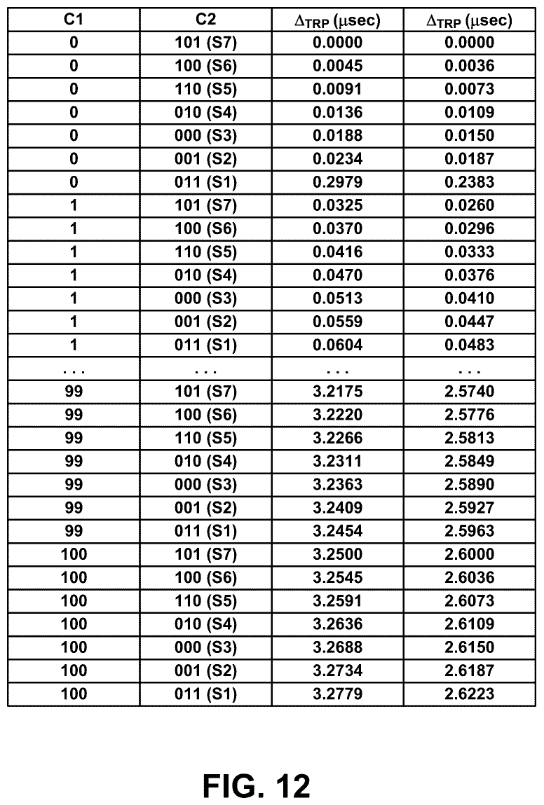

Without wanting to be bound by any particular theory, it is believed that using the first counter C1 and second counter C2 in this manner may improve memory device performance. For example, FIG. 12 lists example charge pump ramp time reductions for program (Δ_{TRP}) and read (Δ_{TRR}) operations in which T_{fp0}=6.5 μsec for program operations and T_{fr}0=5.2 μsec for read operations.

In embodiments, during a power cycle, corresponding first counter C1 and second counter C2 for each block can be stored and retrieved from memory (e.g., a user ROM). Thus, without wanting to be bound by any particular theory, it is believed that first counter C1 and second counter C2 may be used to improve the unselected word line ramp time of charge pumps.

Without wanting to bound by any particular theory, it is believed that on an average random data offers 30% less capacitive load compared to the worst case capacitive load. Without wanting to bound by any particular theory, it is believed that on such random data a total estimated savings of about 0.3×5.2 μsec≈1.5 μsec for read operations and a total estimated savings of about 0.3×6.5 μsec=1.8 μsec for program operations.

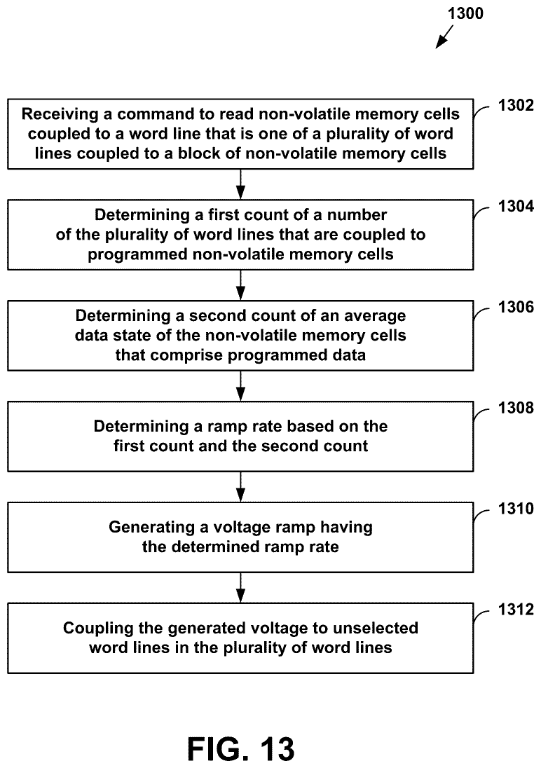

FIG. 13 is a flow diagram of a process 1300 for reading non-volatile memory cells coupled to a word line in a block of non-volatile memory cells. In embodiments, process 1300 may be performed on one or more of memory die 106 (FIG. 1), memory die 200 (FIG. 2A), memory die 242 (FIG. 2B), control die 244 (FIG. 2B) and memory controller 104 (FIGS. 1 and 2A-2B).

At step 1302, receiving a command to read non-volatile memory cells coupled to a word line that is one of a plurality of word lines coupled to a block of non-volatile memory cells.

At step 1304, determining a first count of a number of the plurality of word lines that are coupled to programmed non-volatile memory cells.

At step 1306, determining a second count of an average data state of the non-volatile memory cells that comprise programmed data.

At step 1308, determining a ramp rate based on the first count and the second count.

At step 1310, generating a voltage ramp having the determined ramp rate.

At step 1312, coupling the generated voltage to unselected word lines in the plurality of word lines. The first count and the second count are proxies for a capacitive load of the unselected word lines.

In an embodiment, an apparatus is provided that includes a block of non-volatile memory cells, a plurality of word lines coupled to the non-volatile memory cells, and a charge pump including an output terminal coupled to the plurality of word lines. The charge pump is configured to provide an output signal at the output terminal. The output signal has a rate that is based on a first count of a number of programmed word lines in the plurality of word lines.

In an embodiment, a system is provided that include a block of non-volatile memory cells, a plurality of word lines coupled to the non-volatile memory cells, a charge pump including an output terminal coupled to the plurality of word lines, the charge pump configured to provide an output signal at the output terminal, a first counter configured to generate a first count of a number of programmed word lines in the plurality of word lines, and a processor configured to receive the first count from the first counter, and provide to the charge pump a timing signal based on the first count. The output signal has a rate that is based on the timing signal.

In an embodiment, a method is provided that includes receiving a command to read non-volatile memory cells coupled to a word line that is one of a plurality of word lines coupled to a block of non-volatile memory cells, determining a first count of a number of the plurality of word lines that are coupled to programmed non-volatile memory cells, determining a second count of an average data state of the non-volatile memory cells that comprise programmed data, determining a ramp rate based on the first count and the second count, generating a voltage ramp having the determined ramp rate, and coupling the generated voltage to unselected word lines in the plurality of word lines. The first count and the second count are proxies for a capacitive load of the unselected word lines.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a block of non-volatile memory cells;
a plurality of word lines coupled to the non-volatile memory cells; and
a charge pump comprising an output terminal coupled to the plurality of word lines, the charge pump configured to provide an output signal at the output terminal, the output signal comprising a rate that is based on a first count of a number of programmed word lines in the plurality of word lines.

2. The apparatus of claim 1, wherein the first count comprises a proxy for a capacitive load at the output terminal.

3. The apparatus of claim 1, wherein a capacitive load at the output terminal is based on the first count.

4. The apparatus of claim 1, wherein a capacitive load at the output terminal decreases as the first count increases.

5. The apparatus of claim 1, wherein the rate varies based on a capacitive load at the output terminal.

6. The apparatus of claim 1, wherein the rate decreases as the first count increases.

7. The apparatus of claim 1, wherein the output signal further comprises a rate that is based on a data pattern in the programmed word lines in the plurality of word lines.

8. The apparatus of claim 1, wherein the output signal further comprises a rate that is based on a second count of an average data pattern in the programmed word lines in the plurality of word lines.

9. The apparatus of claim 8, wherein the second count comprises a proxy for a capacitive load at the output terminal.

10. The apparatus of claim 8, wherein a capacitive load at the output terminal is based on the second count.

11. The apparatus of claim 8, wherein:
the non-volatile memory cells comprise a plurality of programmed states; and
a capacitive load at the output terminal increases as the average data pattern increases from a lowest programmed state to a highest programmed state.

12. The apparatus of claim 1, wherein the output signal comprises a voltage ramp comprising the rate.

13. An apparatus comprising:
a block of non-volatile memory cells;
a plurality of word lines coupled to the non-volatile memory cells;
a charge pump comprising an output terminal coupled to the plurality of word lines, the charge pump configured to provide an output signal at the output terminal;
a first counter configured to generate a first count of a number of programmed word lines in the plurality of word lines; and
a processor configured to:
receive the first count from the first counter; and
provide to the charge pump a timing signal based on the first count, wherein the output signal comprises a rate that is based on the timing signal.

14. The apparatus of claim 13, wherein the first count comprises a proxy for a capacitive load at the output terminal.

15. The apparatus of claim 13, wherein a capacitive load at the output terminal decreases as the first count increases.

16. The apparatus of claim 13, wherein the timing signal varies based on a capacitive load at the output terminal.

17. The apparatus of claim 13, wherein the timing signal decreases as the first count increases.

18. The apparatus of claim 13, further comprising:
a second counter configured to generate a second count of an average data pattern of programmed word lines in the plurality of word lines,
wherein the processor is further configured to:
receive the second count from the second counter; and
provide to the charge pump the timing signal based on the first count and the second count.

19. The apparatus of claim 18, wherein the second count comprises a proxy for a capacitive load at the output terminal.

20. A method comprising:
receiving a command to read non-volatile memory cells coupled to a word line that is one of a plurality of word lines coupled to a block of non-volatile memory cells;
determining a first count of a number of the plurality of word lines that are coupled to programmed non-volatile memory cells;
determining a second count comprising an average data state of the non-volatile memory cells that comprise programmed data;
determining a ramp rate based on the first count and the second count;
generating a voltage ramp comprising the determined ramp rate; and
coupling the generated voltage to unselected word lines in the plurality of word lines,
wherein the first count and the second count comprise proxies for a capacitive load of the unselected word lines.
